(19) United States
(12) Patent Application Publication
(10) Pub. No.: US 2026/0351155 A1
(43) Pub. Date: Nov. 5, 2026

(54) ELECTRONIC DEVICE AND METHOD FOR SWITCHING DISPLAY MODE OF DISPLAY

(71) Applicant: Samsung Electronics Co., Ltd., Suwon-si (KR)

(72) Inventors: Donghyeon CHO, Suwon-si (KR); Gyudong EOM, Suwon-si (KR)

(21) Appl. No.: 19/427,209

(22) Filed: Dec. 19, 2025

Related U.S. Application Data
(63) Continuation of application No. PCT/KR2025/013392, filed on Sep. 1, 2025.

(30) Foreign Application Priority Data
Apr. 30, 2025 (KR) 10-2025-0057781
Jun. 4, 2025 (KR) 10-2025-0073251

(51) Int. Cl. G09G 3/20

(52) U.S. Cl. CPC G09G 3/2074; G09G 2300/0452; G09G 2300/0804; G09G 2310/08; G09G 2320/0233; G09G 2320/0247; G09G 2320/028; G09G 2320/0653; G09G 2320/0673; G09G 2330/023; G09G 2354/00; G09G 2358/00; G09G 2360/16

(57) ABSTRACT

An electronic device includes at least one processor and a display including display driver circuitry and a display panel configured to provide a normal display mode and a privacy display mode. The display panel includes a circuit layer, a light emission layer, and a light blocking layer. The display panel includes sub-pixels. The sub-pixels includes a first sub-pixel used for the normal display mode and a second sub-pixel used for both the normal display mode and the privacy display mode. The display driver circuitry is configured to gradually decrease a brightness level provided through the first sub-pixel to a defined brightness level before a display mode provided by the display panel is switched from the normal display mode to the privacy display mode according to a defined event.

### CROSS-REFERENCE TO RELATED APPLICATIONS

This application is a continuation of International Application No. PCT/KR2025/013392 designating the United States, filed on Sep. 1, 2025, in the Korean Intellectual Property Receiving Office and claiming priority to Korean Patent Application Nos. 10-2025-0057781, filed on Apr. 30, 2025, and 10-2025-0073251, filed on Jun. 4, 2025, in the Korean Intellectual Property Office, the disclosures of each of which are incorporated by reference herein in their entireties.

### BACKGROUND

### Field

The disclosure relates to an electronic device and a method for switching a display mode of a display.

### Description of Related Art

An electronic device may include a display. The display may include a display panel and display driver circuitry. The display driver circuitry may be configured to display the image obtained from at least one processor of the electronic device on the display panel. For example, a viewing angle at which the image is displayed (or a viewing angle of the display panel) may be adjusted according to light emission of pixels of the display panel.

The above-described information may be provided as a related art for the purpose of helping to understand the present disclosure. No assertion or determination is made as to whether any of the above-described information may be applied as a prior art related to the present disclosure.

### SUMMARY

According to an example embodiment, an electronic device may comprise: at least one processor comprising processing circuitry. The electronic device may comprise a display including display driver circuitry, and a display panel configured to provide a normal display mode displaying an image having a first viewing angle and a privacy display mode displaying an image having a second viewing angle narrower than the first viewing angle. The display panel may include a circuit layer, a light emission layer disposed on the circuit layer, and a light-blocking layer, disposed above the light emission layer such that the normal display mode and the privacy display mode are provided, including light transmittance portions and a light-blocking portion surrounding the light transmittance portions. The display panel may comprise sub-pixels defined by the circuit layer, the light emission layer, and the light-blocking layer. The sub-pixels may include a first sub-pixel used for the normal display mode, and a second sub-pixel used for both the normal display mode and the privacy display mode. The display driver circuitry may be configured to display an image from the at least one processor using both the first sub-pixel and the second sub-pixel in accordance with the normal display mode. The display driver circuitry may be configured to, before a display mode provided by the display panel is switched from the normal display mode to the privacy display mode in accordance with a defined event, gradually reduce a brightness level provided via the first sub-pixel to a defined brightness level. The display driver circuitry may be configured to, based on the brightness level reduced to the defined brightness level, display an image from the at least one processor using the second sub-pixel from among the first sub-pixel and the second sub-pixel in accordance with the privacy display mode.

According to an example embodiment, an electronic device may comprise at least one processor comprising processing circuitry. The electronic device may comprise a display including display driver circuitry, and a display panel configured to provide a normal display mode displaying an image having a first viewing angle and a privacy display mode displaying an image having a second viewing angle narrower than the first viewing angle. The display panel may include a circuit layer, a light emission layer disposed on the circuit layer, and a light-blocking layer, disposed above the light emission layer such that the normal display mode and the privacy display mode are provided, including light transmittance portions and a light-blocking portion surrounding the light transmittance portions. The display panel may comprise sub-pixels defined by the circuit layer, the light emission layer, and the light-blocking layer. The sub-pixels may include a first sub-pixel used for the normal display mode, and a second sub-pixel used for both the normal display mode and the privacy display mode. The display driver circuitry may be configured to display an image from the at least one processor using the second sub-pixel from among the first sub-pixel and the second sub-pixel in accordance with the privacy display mode. The display driver circuitry may be configured to, before a display mode provided by the display panel is switched from the privacy display mode to the normal display mode in accordance with a defined event, gradually increase a brightness level provided via the first sub-pixel to a defined brightness level. The display driver circuitry may be configured to, based on the brightness level increased to the defined brightness level, display an image from the at least one processor using both the first sub-pixel and the second sub-pixel in accordance with the normal display mode.

According to an example embodiment, an electronic device may comprise at least one processor comprising processing circuitry. The electronic device may comprise memory storing instructions. The electronic device may comprise a display set to provide a first display mode observable at a first viewing angle and a second display mode observable at a second viewing angle narrower than the first viewing angle. The display may include a pixel layer including a first pixel group and a second pixel group. The display may include a light-blocking layer forming a first light transmittance portion, disposed above the first pixel group, having a first width corresponding to the first viewing angle, and a second light transmittance portion, disposed above the second pixel group, having a second width smaller than the first width corresponding to the second viewing angle. The instructions, when executed by the at least one processor individually or collectively, may cause the electronic device to: display, at the first display mode, via the first pixel group and the second pixel group, a first screen corresponding to the first display mode. The instructions, when executed by the at least one processor individually or collectively, may cause the electronic device to display, at the second display mode, via the second pixel group, a second screen corresponding to the second display mode. The first pixel group may be turned off or turned on to have a limited grayscale. The instructions, when executed by the at least one processor individually or collectively, may cause the electronic device to, based on switching from the first display mode to the second display mode or from the second display mode to the first display mode, display, via at least a portion of at least one of the first pixel group or the second pixel group, a plurality of transition frames between the first screen and the second screen.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a diagram illustrating an example of changing a viewing angle of an image according to various embodiments.

FIG. 2 is a block diagram illustrating an example configuration of an electronic device according to various embodiments.

FIG. 3 is a diagram illustrating an example configuration of a display panel including sub-pixels arranged according to according to various embodiments.

FIG. 4 is a cross-sectional view taken along line A-B of FIG. 3 according to various embodiments.

FIG. 5 is a cross-sectional view taken along line C-D of FIG. 3 according to various embodiments.

FIG. 6 is a diagram illustrating an example configuration of a display panel including sub-pixels arranged according to various embodiments.

FIG. 7A includes graphs illustrating a difference in brightness level caused in a display when switching a display mode of a display according to various embodiments.

FIG. 7B includes graphs illustrating a brightness level of a display, gradually changed while switching a display mode of a display according to various embodiments.

FIG. 8 is a diagram including a graph illustrating an example method of gradually changing a grayscale level to gradually change a brightness level provided through a first sub-pixel used for a normal display mode according to various embodiments.

FIG. 9A is a graph illustrating a brightness level according to a luminance value in a display mode of a display according to various embodiments.

FIG. 9B includes a diagram and a graph illustrating an example method of gradually changing a luminance value to gradually change a brightness level provided through a second sub-pixel used for both a normal display mode and a privacy display mode according to various embodiments.

FIG. 10 is a diagram illustrating example commands transmitted from at least one processor to display driver circuitry, a change in time intervals during which the commands are transmitted, and a change in a period during which the commands are transmitted, while a display mode of a display is switched according to various embodiments.

FIG. 11 includes graphs illustrating an example of gradually changing a grayscale level associated with a first sub-pixel, gradually changing a luminance value associated with a second sub-pixel, and gradually changing a brightness level of a display, while a display mode of the display is switched from a normal display mode to a privacy display mode according to various embodiments.

FIG. 12 includes graphs illustrating an example of gradually changing a grayscale level associated with a first sub-pixel, gradually changing a luminance value associated with a second sub-pixel, and gradually changing a brightness level of a display, while a display mode of the display is switched from a normal display mode to a privacy display mode according to various embodiments.

FIG. 13 includes graphs illustrating an example of gradually changing a grayscale level associated with a first sub-pixel, gradually changing a luminance value associated with a second sub-pixel, and gradually changing a brightness level of a display, while a display mode of the display is switched from a privacy display mode to a normal display mode according to various embodiments.

FIG. 14 is a block diagram of an example electronic device in a network environment according to various embodiments.

FIG. 15 is a block diagram illustrating an example configuration of a display module according to various embodiments.

### DETAILED DESCRIPTION

Terms used in the present disclosure are used to describe various example embodiments, and are not intended to limit a range of the disclosure. A singular expression may include a plural expression unless the context clearly means otherwise. Terms used herein, including a technical or a scientific term, may have the same meaning as those generally understood by a person with ordinary skill in the art described in the present disclosure. Among the terms used in the present disclosure, terms defined in a general dictionary may be interpreted as identical or similar meaning to the contextual meaning of the relevant technology and are not interpreted as ideal or excessively formal meaning unless explicitly defined in the present disclosure. In some cases, even terms defined in the present disclosure may not be interpreted to exclude embodiments of the present disclosure.

The present disclosure, the term ‘greater than’ or ‘less than’ may be used to determine whether a particular condition is satisfied or fulfilled, but this is only a description to express an example and does not exclude description of 'greater than or equal to' or 'less than or equal to'. A condition described as 'greater than or equal to ' may be replaced with 'greater than', a condition described as 'less than or equal to' may be replaced with 'less than', and a condition described as ' greater than or equal to and less than' may be replaced with 'greater than and less than or equal to'. The term “one” is not limited to being directly on or contacting, but may include being above or over or below with other elements in between.

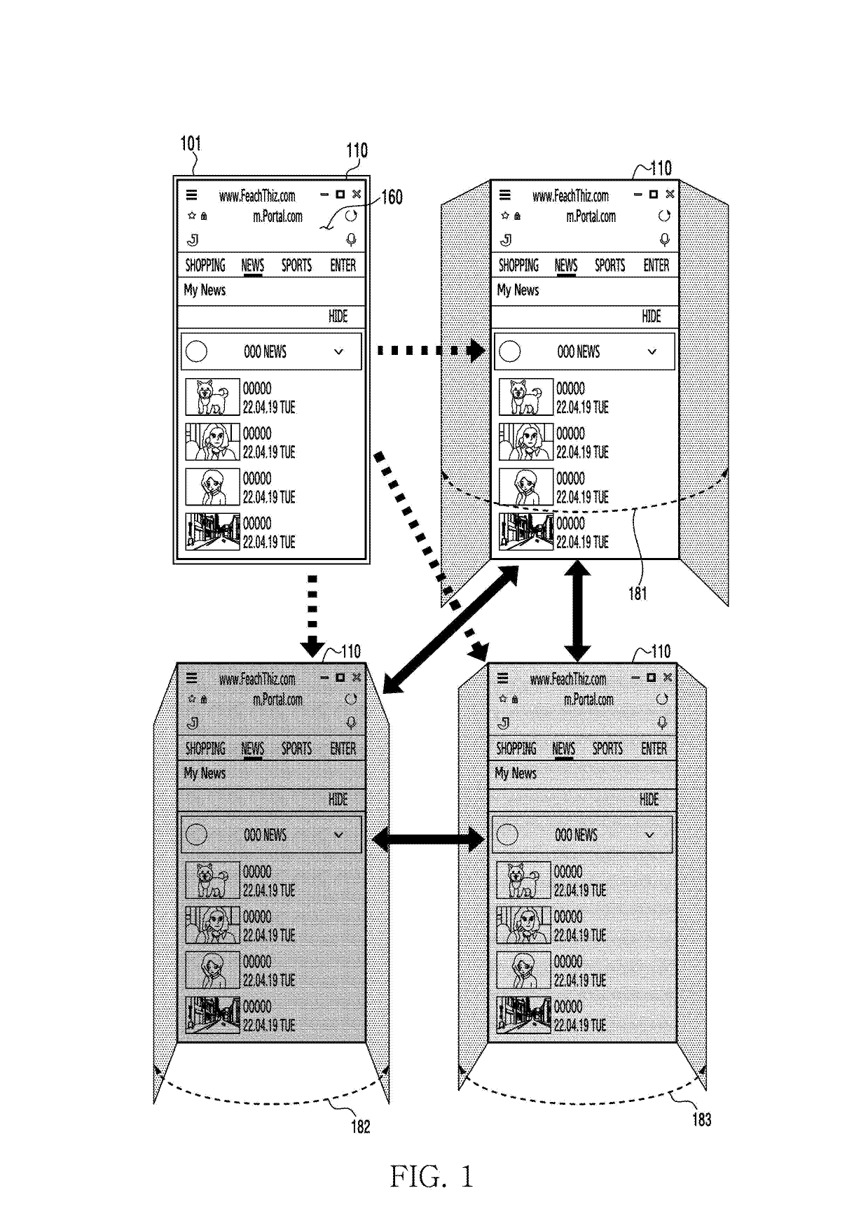

FIG. 1 is a diagram illustrating an example of changing a viewing angle of an image according to various embodiments.

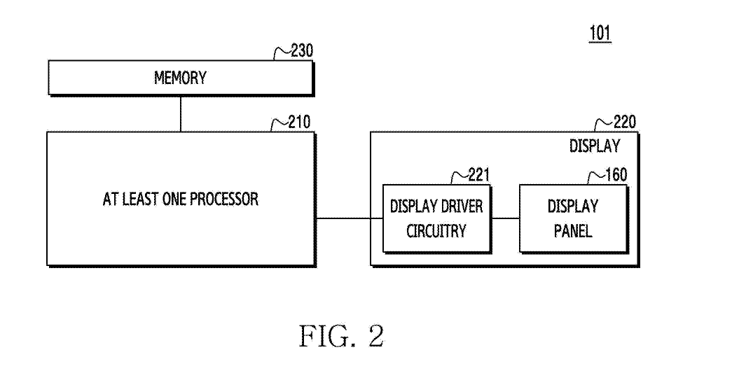

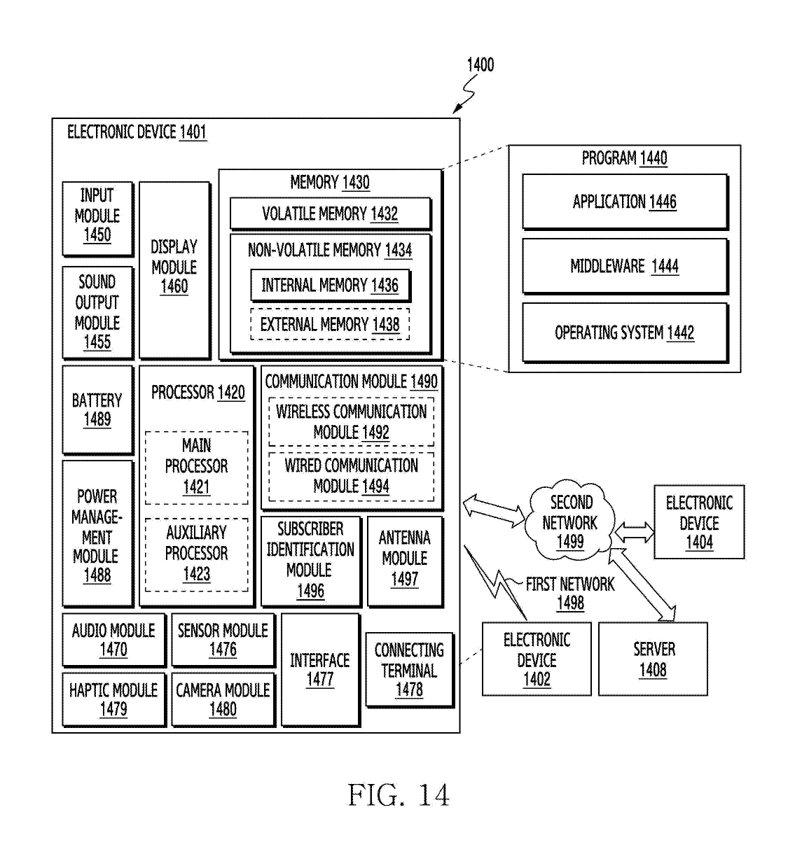

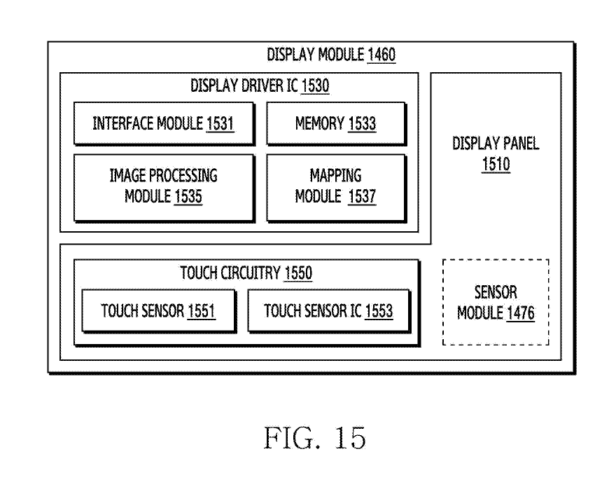

Referring to FIG. 1, an electronic device 101 (e.g., the electronic device 1401 of FIG. 14) may display an image 110 on a display panel 160 (e.g., the display panel 160 of FIG. 2, the display panel 1510 of FIG. 15). The image 110 may include one or more contents (or one or more media contents) (or one or more visual contents). The image 110 may include one or more user interface (UI) objects configured to provide or execute a function in response to an input. The image 110 may be displayed on the display panel 160 to provide information.

The electronic device 101 may display an image 110 having a viewing angle 181 through the display panel 160 (or on the display panel 160). For example, the viewing angle 181 of the image 110 may be wider than a viewing angle 182 of the image 110 and a viewing angle 183 of the image 110 described below. For example, the image 110 having the viewing angle 181 may be displayed on the display panel 160 according to a normal display mode (or a normal mode). For example, the viewing angle 181 may be wider than a first threshold viewing angle (e.g., the viewing angle 182) and may be wider than a second threshold viewing angle (e.g., the viewing angle 183) wider than the first threshold viewing angle. For example, visibility (or a quality in which contents in the image 110 are perceived) of the image 110 viewable from inside the viewing angle 181 may be higher than visibility of the image 110 viewable from outside the viewing angle 181. For example, visibility of the image 110 viewable from inside the viewing angle 182 may be higher than visibility of the image 110 viewable from outside the viewing angle 182. For example, visibility of the image 110 viewable from inside the viewing angle 183 may be higher than visibility of the image 110 viewable from outside the viewing angle 183.

The electronic device 101 may provide a function (or feature) for user privacy with respect to display on the display panel 160. For example, the electronic device 101 may provide a privacy display mode, which is a display mode for narrowing a viewing angle of at least a portion of the image 110 displayed through the display panel 160, for the function. The privacy display mode may include a first privacy display mode. As a non-limiting example, the privacy display mode may further include a second privacy display mode.

The first privacy display mode may be described as a display mode providing the first threshold viewing angle (e.g., the viewing angle 182). For example, the electronic device 101 may display, through the display panel 160, the image 110 having the viewing angle 182, which is the threshold viewing angle (or narrower than the threshold viewing angle), according to the first privacy display mode. The first privacy display mode may be described as a mode for displaying the image 110 by emitting light from sub-pixels included in second sub-pixel groups 312 from among first sub-pixel groups 311 and the second sub-pixel groups 312 described below. For example, since the viewing angle 181 is wider than the viewing angle 182, visibility of the image 110 from a left (or right) space of the display panel 160 when the image 110 is displayed according to the normal display mode may be higher than visibility of the image 110 from the left (or right) space of the display panel 160 when the image 110 is displayed according to the first privacy display mode.

The first privacy display mode may be changed or switched from the normal display mode. For example, the electronic device 101 may change displaying the image 110 having the viewing angle 181 into displaying the image 110 having the viewing angle 182, based on the first privacy display mode changed from the normal display mode. For example, the electronic device 101 may, based on changing the normal display mode to the first privacy display mode, cease (or terminate) (or deactivate) displaying the image 110 having the viewing angle 181 and display the image 110 having the viewing angle 182. For example, the electronic device 101 may change displaying the image 110 having the viewing angle 182 into displaying the image 110 having the viewing angle 181, based on changing the first privacy display mode to the normal display mode. As a non-limiting example, the first threshold viewing angle may be described as a narrowest viewing angle capable of being provided through the display panel 160.

The first privacy display mode may be changed or switched from the second privacy display mode. For example, the electronic device 101 may, based on the first privacy display mode changed from the second privacy display mode (which will be described in greater detail below), change displaying the image 110 having the viewing angle 183 to displaying the image 110 having the viewing angle 182. For example, the electronic device 101 may, based on changing the second privacy display mode to the first privacy display mode, cease (or terminate) (or deactivate) displaying the image 110 having the viewing angle 183 and display the image 110 having the viewing angle 182. For example, the electronic device 101 may, based on changing the first privacy display mode to the second privacy display mode, change displaying the image 110 having the viewing angle 182 to displaying the image 110 having the viewing angle 183.

The second privacy display mode may be described as a privacy display mode providing a viewing angle (e.g., the viewing angle 183) that is wider than the first threshold viewing angle and narrower than or equal to the second threshold viewing angle. The second privacy display mode may be described as a privacy display mode that adjusts visibility from a peripheral space of the display panel 160. For example, the visibility from the peripheral space of the display panel 160 provided according to the second privacy display mode may differ from visibility from a peripheral space of the display panel 160 provided according to the first privacy display mode. For example, the second privacy display mode may be described as a mode for displaying the image 110 by emitting light from sub-pixels included in both the first sub-pixel groups 311 and the second sub-pixel groups 312 described below. In the second privacy display mode, a range of a grayscale level represented by each of the sub-pixels included in the first sub-pixel groups 311 may be limited. For example, since the viewing angle 183 is wider than the viewing angle 182, visibility of the image 110 from a left (or right) space of the display panel 160 when displaying the image 110 according to the second privacy display mode may be higher than visibility of the image 110 from the left (or right) space of the display panel 160 when displaying the image 110 according to the first privacy display mode.

For example, the electronic device 101 may display, on the display panel 160, the image 110 having the viewing angle 183, wider than the first threshold viewing angle and narrower than the second threshold viewing angle, according to the second privacy display mode. The second threshold viewing angle may be described as a widest viewing angle capable of being provided according to the second privacy display mode. The viewing angle 183, which is a viewing angle provided according to the second privacy display mode, may be between the first threshold viewing angle and the second threshold viewing angle. The second privacy display mode may be described as a display mode between the normal display mode and the first privacy display mode. The second privacy display mode may be described as a display mode that adjusts a viewing angle of the image displayed on the display panel 160 between the first threshold viewing angle and the second threshold viewing angle. For example, the electronic device 101 may change displaying the image 110 having the viewing angle 181 to displaying the image 110 having the viewing angle 183, based on the second privacy display mode changed from the normal display mode. For example, the electronic device 101 may, based on changing the normal display mode to the second privacy display mode, cease (or terminate) (or deactivate) displaying the image 110 having the viewing angle 181 and display the image 110 having the viewing angle 183. For example, the electronic device 101 may, based on the second privacy display mode changed from the first privacy display mode, change displaying the image 110 having the viewing angle 182 to displaying the image 110 having the viewing angle 183. For example, the electronic device 101 may, based on changing the first privacy display mode to the second privacy display mode, cease (or terminate) (or deactivate) displaying the image 110 having the viewing angle 182 and display the image 110 having the viewing angle 183. For example, the electronic device 101 may, based on changing the second privacy display mode to the normal display mode, change displaying the image 110 having the viewing angle 183 to displaying the image 110 having the viewing angle 181.

FIG. 2 is a block diagram illustrating an example configuration of an electronic device according to various embodiments.

Referring to FIG. 2, the electronic device 101 may comprise at least one processor 210 comprising processing circuitry, a display 220, and memory 230. The electronic device 101 may comprise at least a portion of the electronic device 1401 of FIG. 14, or may correspond to at least a portion of the electronic device 1401 of FIG. 14.

At least one processor 210 may comprise at least a portion of the processor 1420 of FIG. 14, or may correspond to at least a portion of the processor 1420 of FIG. 14. At least one processor 210 may include a central processing unit (CPU), (e.g., comprising processing circuitry) and a display processing unit (DPU) (e.g., comprising processing circuitry). As a non-limiting example, at least one processor 210 may further include a graphic processing unit (GPU) (e.g., comprising processing circuitry). The at least one processor 210 may be configured to execute instructions stored in the memory 230. For example, the at least one processor 210 may, based on executing the instructions, obtain or generate an image to be displayed through the display panel 160. For example, the at least one processor 210 may, based on executing the instructions, determine a display mode (e.g., the normal display mode or the privacy display mode) to be applied to the image. For example, the at least one processor 210 may, based on executing the instructions, transmit the image from the at least one processor 210 to the display driver circuitry 221.

As a non-limiting example, the at least one processor 210 may perform at least a portion of operations described in the present disclosure, using a trained model (e.g., a generative artificial intelligence (AI) model). For example, the at least one processor 210 may, using the trained model, determine to change the normal display mode to the privacy display mode and/or determine to change the privacy display mode to the normal display mode.

As a non-limiting example, the at least one processor 210 may, based on a determination to change the normal display mode to the privacy display mode, transmit at least one command indicating the privacy display mode to the display driver circuitry 221. For example, the display driver circuitry 221 may, based on the at least one command, change the normal display mode to the privacy display mode.

As a non-limiting example, the at least one processor 210 may, based on a determination to change the privacy display mode to the normal display mode, transmit at least one command indicating the normal display mode to the display driver circuitry 221. For example, the display driver circuitry 221 may, based on the at least one command, change the privacy display mode to the normal display mode.

The display 220 may include at least a portion of the display module 1460 of FIG. 14, or may correspond to at least a portion of the display module 1460 of FIG. 14. As a non-limiting example, the display 220 may operate or be driven for a command mode, a video mode, a hybrid video mode of a mobile industry processor interface (MIPI) display serial interface (DSI), and/or an adaptive refresh panel (ARP).

The display 220 may include display driver circuitry (or display driver integrated circuitry) 221 and a display panel 160.

The display driver circuitry 221 may include at least a portion of the display driver IC 1530 of FIG. 15, or may correspond to at least a portion of the display driver IC 1530 of FIG. 15. The display driver circuitry 221 may control the display panel 160 to display the image received from the at least one processor 210 through the display panel 160. For example, the display driver circuitry 221 may identify a display mode (e.g., the normal display mode or the privacy display mode) to be applied to the image according to at least one command received from the at least one processor 210. The display driver circuitry 221 may apply, to each of sub-pixels to be used for displaying the image, a data voltage corresponding to a grayscale level regarding a position of the image corresponding to each of the sub-pixels, according to the identified display mode. For example, the data voltage may be applied to each of the sub-pixels of the display panel 160 through source driver circuitry (or data driver circuitry) (not illustrated in the present disclosure) included in the display 220. The source driver circuitry may connect the display driver circuitry 221 and the display panel 160. As a non-limiting example, the source driver circuitry may be integrated with the display driver circuitry 221. As a non-limiting example, the source driver circuitry may be integrated with the display panel 160. As a non-limiting example, the source driver circuitry may connect the display driver circuitry 221 and the display panel 160, and may be a hardware component of the display 220 that is separate from the display driver circuitry 221 and the display panel 160. A data voltage inputted to the display panel 160 through the source driver circuitry may be applied to each of the sub-pixels through a data line included in the display panel 160.

The display driver circuitry 221 may transmit a scan signal to each of the sub-pixels of the display panel 160 through gate driver circuitry (or scan driver circuitry) (not illustrated in the present disclosure) included in the display driver circuitry 221 or located outside the display driver circuitry 221. The scan signal transmitted from the gate driver circuitry may be transmitted to the sub-pixels through a plurality of scan lines.

The display panel 160 may include at least a portion of the display panel 1510 of FIG. 15 or may correspond to at least a portion of the display panel 1510 of FIG. 15.

The memory 230 may include one or more storage media (or storage mediums). For example, the one or more storage media may include a permanent memory such as a hard drive, a flash memory, and a read-only memory (ROM), a semi-permanent memory such as a random access memory (RAM), any other suitable type of storage assembly, or any combination thereof. The memory 230 may include a cache memory, which is one or more different types of memory used to temporarily store data for a function (or feature) of the electronic device 101. The memory 230 may be fixedly embedded in the electronic device 101, or may be incorporated onto one or more suitable types of components (e.g., a subscriber identity module (SIM) card and/or a secure digital (SD) memory card) that are repeatedly insertable into and removable from the electronic device 101. For example, the memory 230 may include at least a portion of the memory 1430 of FIG. 14, or may correspond to at least a portion of the memory 1430 of FIG. 14.

The memory 230 may store one or more programs such as an operating system program, a firmware program, a media playback program, a media editing program, a program for communication with other users, a translation program, a digital assistant program, and/or any other suitable program. For example, each of the one or more programs may be configured to be executed individually or collectively by the at least one processor 210. The one or more programs may include instructions.

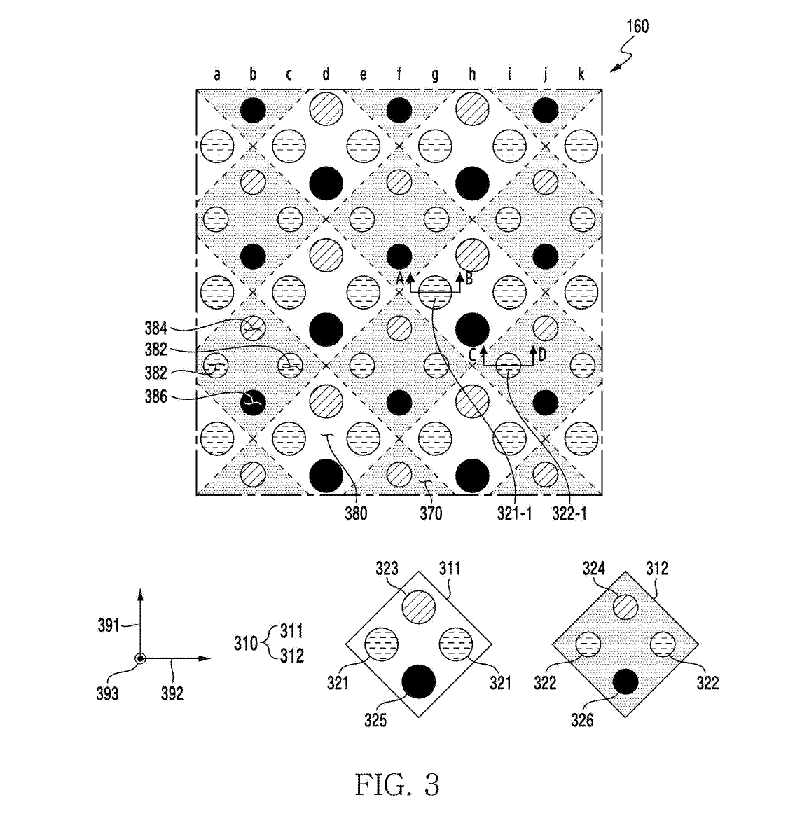

The display 220 may support the normal display mode and the privacy display mode. As a non-limiting example, a display mode of the display 220 may include the normal display mode and the privacy display mode. For example, the display panel 160 included in the display 220 may include a structure for supporting the normal display mode and the privacy display mode. The structure or configuration of an example display panel is illustrated and described in greater detail below with reference to FIG. 3.

FIG. 3 is a diagram illustrating an example configuration of a display panel including sub-pixels arranged according to various embodiments.

Referring to FIG. 3, the display panel 160 according to the first example configuration may include a plurality of sub-pixels 310. The sub-pixels 310 may be used to display an image. The sub-pixels 310 may include sub-pixels configured to emit light having a first color (e.g., a green color), sub-pixels configured to emit light having a second color (e.g., a blue color), and sub-pixels configured to emit light having a third color (e.g., a red color). One of the sub-pixels configured to emit light having the first color and one of the sub-pixels configured to emit light having the second color may be included in one of first pixels (not illustrated in the present disclosure). One of the sub-pixels configured to emit light having the first color and one of the sub-pixels configured to emit light having the third color may be included in one of second pixels (not illustrated in the present disclosure).

First sub-pixel groups 311 and second sub-pixel groups 312 may be defined in the display panel 160 with respect to a display mode (e.g., the normal display mode and the privacy display mode). As a non-limiting example, the first sub-pixel groups 311 may be used for the normal display mode from among the normal display mode and the privacy display mode. As a non-limiting example, the first sub-pixel groups 311 may also be used for the privacy display mode (e.g., the second privacy display mode). As a non-limiting example, when the first sub-pixel groups 311 are used for the privacy display mode, each of sub-pixels included in the first sub-pixel groups 311 may indicate a grayscale level within a limited range of grayscale levels (e.g., narrower than a range of grayscale levels represented by each of sub-pixels included in the second sub-pixel groups 312 used for the privacy display mode). As a non-limiting example, the second sub-pixel groups 312 may be used for both the normal display mode and the privacy display mode.

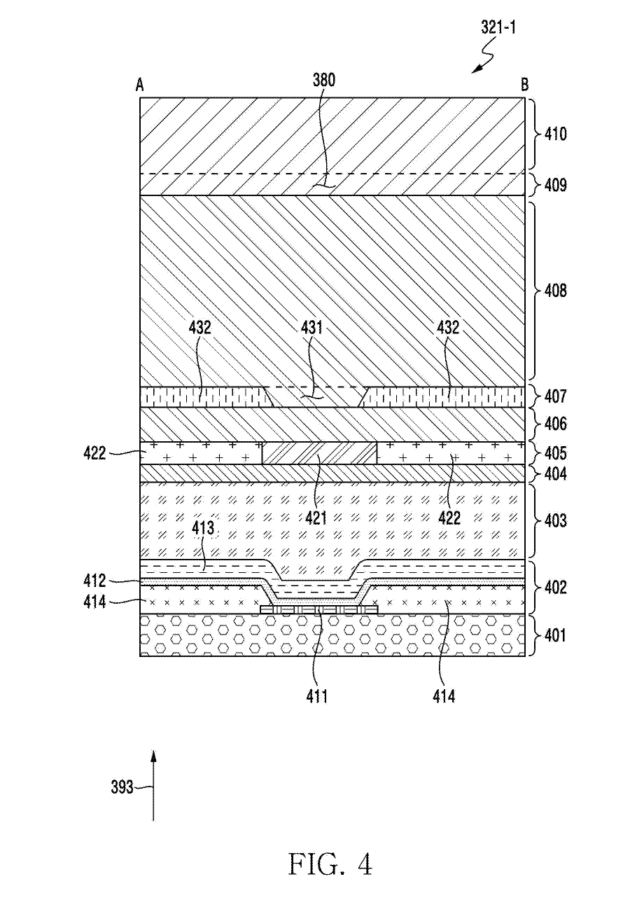

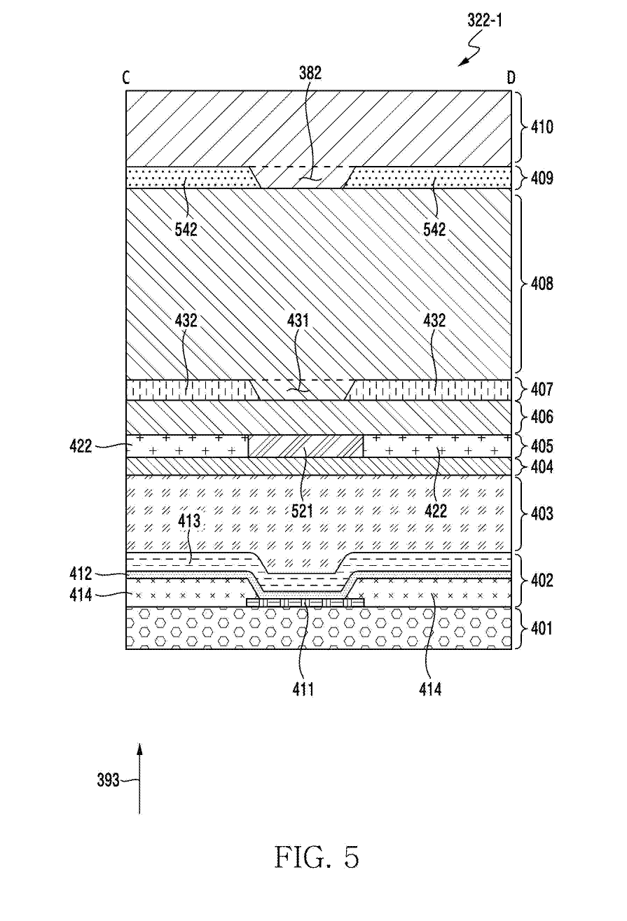

The sub-pixels 310 may be defined by not only a circuit layer (described with reference to FIGS. 4 and 5) and a light emission layer (described with reference to FIGS. 4 and 5) but also a black matrix (BM) layer (or a viewing angle adjustment layer) (or a field of illumination (FOI) adjustment layer). The first sub-pixel groups 311 may include first sub-pixels 321 configured to emit light having the first color and included (or positioned) in each of columns (e.g., column a, column c, column e, column g, column i, and column k) defined in a vertical direction 391, third sub-pixels 323 configured to emit light having the second color and included in each of columns (e.g., column d and column h) defined in the vertical direction 391, and fifth sub-pixels 325 configured to emit light having the third color and included in each of columns (e.g., column d and column h) defined in the vertical direction 391. The second sub-pixel groups 312 may include second sub-pixels 322 configured to emit light having the first color and included in each of columns (e.g., column a, column c, column e, column g, column i, and column k) defined in the vertical direction 391, fourth sub-pixels 324 configured to emit light having the second color and included in columns (e.g., column b, column f, and column j) defined in the vertical direction 391, and sixth sub-pixels 326 configured to emit light having the third color and included in columns (e.g., column b, column f, and column j) defined in the vertical direction 391.

The first sub-pixels 321 may be arranged in the vertical direction 391 within a column. The second sub-pixels 322 may be arranged in the vertical direction 391 within a column. The second sub-pixels 322 may alternate with the first sub-pixels 321 in the vertical direction 391 within a column. The first sub-pixels 321 within a column may be respectively disposed, in a horizontal direction 392, alongside the first sub-pixels 321 within another column. The second sub-pixels 322 within a column may be respectively disposed, in the horizontal direction 392, alongside the second sub-pixels 322 within another column.

The third sub-pixels 323 may be arranged in the vertical direction 391 within a column. The fifth sub-pixels 325 may be arranged in the vertical direction 391 within a column. The fifth sub-pixels 325 may alternate with the third sub-pixels 323 in the vertical direction 391 within a column. The third sub-pixels 323 within a column may be respectively disposed, in the horizontal direction 392, alongside the sixth sub-pixels 326 within another column. The fifth sub-pixels 325 within a column may be respectively disposed, in the horizontal direction 392, alongside the fourth sub-pixels 324 within another column.

The fourth sub-pixels 324 may be arranged in the vertical direction 391 within a column. The sixth sub-pixels 326 may be arranged in the vertical direction 391 within a column. The sixth sub-pixels 326 may alternate with the fourth sub-pixels 324 in the vertical direction 391 within a column.

A second FOI of light emitted from the second sub-pixels 322 may be narrower than a first FOI of light emitted from the first sub-pixels 321. The second FOI may be narrower than the first FOI, according to a difference between a size of a light transmittance portion (e.g., a light transmittance portion 382) in the BM layer arranged with respect to each of the second sub-pixels 322 and a size of a light transmittance portion (e.g., a light transmittance portion 380) in the BM layer arranged with respect to each of the first sub-pixels 321. The second sub-pixels 322 may be observable at a second viewing angle, and the first sub-pixels 321 may be observable at a first viewing angle wider than the second viewing angle.

A fourth FOI of light emitted from the fourth sub-pixels 324 may be narrower than a third FOI of light emitted from the third sub-pixels 323. The fourth FOI may be narrower than the third FOI according to a difference between a size of a light transmittance portion (e.g., a light transmittance portion 384) in the BM layer arranged with respect to each of the fourth sub-pixels 324 and a size of a light transmittance portion (e.g., a light transmittance portion 380) in the BM layer arranged with respect to each of the third sub-pixels 323. The fourth sub-pixels 324 may be observable at a fourth viewing angle, and the third sub-pixels 323 may be observable at a third viewing angle wider than the fourth viewing angle.

A sixth FOI of light emitted from the sixth sub-pixels 326 may be narrower than a fifth FOI of light emitted from the fifth sub-pixels 325. The sixth FOI may be narrower than the fifth FOI according to a difference between a size of a light transmittance portion (e.g., a light transmittance portion 386) in the BM layer arranged with respect to each of the sixth sub-pixels 326 and a size of a light transmittance portion (e.g., a light transmittance portion 380) in the BM layer arranged with respect to each of the fifth sub-pixels 325. The sixth sub-pixels 326 may be observable at a sixth viewing angle, and the fifth sub-pixels 325 may be observable at a fifth viewing angle wider than the sixth viewing angle.

The BM layer may include light transmittance portions (e.g., including the light transmittance portion 380, the light transmittance portion 382, the light transmittance portion 384, and the light transmittance portion 386) and a BM portion 370 surrounding the light transmittance portions.

Each of the light transmittance portions may be configured to transmit light emitted from a light-emitting portion (e.g., including a light emitting diode (LED) or an organic LED (OLED)) in each of the sub-pixels 310. As a non-limiting example, each of the light transmittance portions may be an opening. The opening may be filled with a light-transmitting material (e.g., the same material as a material included in a window layer) as described with reference to FIGS. 4 and 5. A size of a portion of the light transmittance portions may be different from a size of another portion of the light transmittance portions. For example, a size of the light transmittance portion 380 may be greater than a size of the light transmittance portion 382, a size of the light transmittance portion 384, and a size of the light transmittance portion 386. As a non-limiting example, a size of the light transmittance portion 382 may be different from a size of the light transmittance portion 384. As a non-limiting example, a size of the light transmittance portion 382 may be different from a size of the light transmittance portion 386. As a non-limiting example, a size of the light transmittance portion 384 may be different from a size of the light transmittance portion 386.

The light transmittance portion 380 may overlap, in a direction 393 of a front side of the display panel 160, each of the first sub-pixel groups 311. The light transmittance portion 380 may be aligned, in the direction 393, with a center of each of the first sub-pixel groups 311.

The light transmittance portion 382 may overlap, in the direction 393, each of the second sub-pixels 322. The light transmittance portion 382 may overlap, in the direction 393, a center of each of the second sub-pixels 322. The light transmittance portion 384 may overlap, in the direction 393, each of the fourth sub-pixels 324. The light transmittance portion 384 may overlap, in the direction 393, a center of each of the fourth sub-pixels 324. The light transmittance portion 386 may overlap, in the direction 393, each of the sixth sub-pixels 326. The light transmittance portion 386 may overlap, in the direction 393, a center of each of the sixth sub-pixels 326.

The BM portion 370 may be configured to block at least a portion of light emitted from a light-emitting portion in each of the sub-pixels 310.

The light transmittance portions and the BM portion described above are described in greater detail below with reference to FIGS. 4 and 5.

FIG. 4 is a cross-sectional view taken along line A-B of FIG. 3 according to various embodiments.

Referring to FIG. 4, the display panel 160 may include a circuit layer 401, a light emission layer 402, an encapsulation layer 403, a touch-sensitive layer 404, a color filter layer 405, a first thickness compensation layer 406, a first BM layer 407, a second thickness compensation layer 408, a second BM layer 409, and a window layer 410. However, the present disclosure is not limited thereto. One or more layers (e.g., the touch-sensitive layer 404, the color filter layer 405, the first thickness compensation layer 406, the first BM layer 407, and/or the second thickness compensation layer 408) may not be included in the display panel 160 or may be omitted from the display panel 160.

For example, each of the sub-pixels 310 may be defined by the circuit layer 401, the light emission layer 402, and the second BM layer 409 (or the circuit layer 401, the light emission layer 402, the color filter layer 405, the first BM layer 407, and the second BM layer 409).

The circuit layer 401 may include a plurality of transistors and a plurality of data lines. The plurality of transistors may be used to control emitting light from the sub-pixels 310. The data lines may be used to apply, to the sub-pixels 310, a data voltage generated or obtained by the display driver circuitry 221.

The light emission layer 402 may be disposed on or above the circuit layer 401. The light emission layer 402 may cover the circuit layer 401. The light emission layer 402 may include a plurality of light-emitting portions (e.g., LEDs or OLEDs). For example, each of the light-emitting portions may include a layer 411 including an anode electrode, a layer 412 disposed on the layer 411 and including a light-emitting material (or an organic light-emitting material), and a layer 413 disposed on the layer 412 and including a cathode electrode. Unlike the layer 411, the layers 412 and 413 may be partially disposed on a dielectric portion of the light emission layer 402 described below.

The light emission layer 402 may include a dielectric portion 414 surrounding the light-emitting portions and defining peripheries of the light-emitting portions. The dielectric portion 414 may be described as a pixel definition layer (PDL) 414.

The encapsulation layer 403 may cover the light emission layer 402. The encapsulation layer 403 may be disposed on the light emission layer 402. The encapsulation layer 403 may encapsulate the light emission layer 402 to reduce injection of fine foreign substances (or fine external objects) into the light emission layer 402.

The touch-sensitive layer 404 may be disposed on or above the encapsulation layer 403. The touch-sensitive layer 404 may be configured to identify a touch input on the display panel 160 (e.g., a touch input caused by a finger or a stylus positioned on and/or above the window layer 410). FIGS. 4 and 5 illustrate the touch-sensitive layer 404 disposed between the encapsulation layer 403 and the color filter layer 405, but this is merely an example. A position of the touch-sensitive layer 404 may be changed.

The color filter layer 405 may be disposed on or above the touch-sensitive layer 404. The color filter layer 405 may include color filter portions (e.g., a color filter portion 421) respectively aligned, in the direction 393, with the light-emitting portions, and a BM portion 422 surrounding the color filter portions. For example, the BM portion 422 may be configured to block light. For example, each of the color filter portions may be configured to transmit light having the same color as a color of light emitted from a light-emitting portion aligned with each of the color filter portions. For example, the color filter portion 421 may be configured to transmit light having the first color, which is a color of light emitted from a light-emitting portion included in the first sub-pixel 321-1 among the first sub-pixels 321.

The first thickness compensation layer 406 may be disposed on or above the color filter layer 405. The first thickness compensation layer 406 may be included in the display panel 160 to compensate for a thickness of the display panel 160.

The first BM layer 407 may be disposed on or above the first thickness compensation layer 406. The first BM layer 407 may include light transmittance portions 431 respectively aligned with the light-emitting portions in the direction 393, and a BM portion 432 surrounding the light transmittance portions 431. As a non-limiting example, each of the light transmittance portions 431 may be an opening. The opening may be filled with a material included in the second thickness compensation layer 408. The light transmittance portions 431 may be configured to transmit light. The BM portion 432 may be configured to block light. Unlike the second BM layer 409 described below, the first BM layer 407 may be included in the display panel 160 to reduce transmission of light emitted from a light-emitting portion in a sub-pixel to (or toward) another sub-pixel adjacent to the sub-pixel. As a non-limiting example, the BM portion 432 may be omitted from a stacked structure related to FIG. 4 for a wider viewing angle. For example, the BM portion 432 may not be included in a stacked structure related to a first sub-pixel 321-1 of the first sub-pixels 321, and may be included in a stacked structure related to a second sub-pixel 322-1 of the second sub-pixels 322.

The second thickness compensation layer 408 may be disposed on or above the first BM layer 407. The second thickness compensation layer 408 may be included in the display panel 160 to compensate for a thickness of the display panel 160. The second thickness compensation layer 408 may cover the BM portion 432. When each of the light transmittance portions 431 is an opening, the second thickness compensation layer 408 may cover a portion of the first thickness compensation layer 406 or may contact a portion of the first thickness compensation layer 406.

As a non-limiting example, the second thickness compensation layer 408 may include a layer and another layer. For example, a material included in the layer may be the same as a material included in the first thickness compensation layer 406. For example, a material included in the other layer may be different from a material included in the layer.

The second BM layer 409 may be disposed on or above the second thickness compensation layer 408. The second BM layer 409 may correspond to the BM layer defined in the description of FIG. 3. The second BM layer 409 may include light transmittance portions. For example, the second BM layer 409 may include a light transmittance portion 380, a light transmittance portion 382, a light transmittance portion 384, and a light transmittance portion 386. For example, a first sub-pixel 321-1 of the first sub-pixels 321 may include the light transmittance portion 380 (or a portion of the light transmittance portion 380). The second BM layer 409 may include a BM portion (not illustrated in FIG. 4, illustrated in FIG. 5) defining the light transmittance portions (or surrounding the light transmittance portions).

As a non-limiting example, the BM portion of the second BM layer 409 may be included in a stacked structure related to FIG. 4. For example, the stacked structure related to FIG. 4 may include both the BM portion 432 of the first BM layer 407 and the BM portion of the second BM layer 409, may include one of the BM portion 432 of the first BM layer 407 and the BM portion of the second BM layer 409, or may include neither the BM portion 432 of the first BM layer 407 nor the BM portion of the second BM layer 409. For example, when the stacked structure related to FIG. 4 includes both the BM portion 432 of the first BM layer 407 and the BM portion of the second BM layer 409, a size of a light transmittance portion of the first BM layer 407 aligned with a light-emitting portion (e.g., a first sub-pixel 321-1 of the first sub-pixels 321) may be substantially the same as a size of a light transmittance portion of the second BM layer 409 aligned with the light-emitting portion. However, the present disclosure is not limited thereto. For example, when the stacked structure related to FIG. 4 includes both the BM portion 432 of the first BM layer 407 and the BM portion of the second BM layer 409, a size of a light transmittance portion of the first BM layer 407 aligned with a light-emitting portion (e.g., a first sub-pixel 321-1 of the first sub-pixels 321) may be different from a size of a light transmittance portion of the second BM layer 409 aligned with the light-emitting portion. For example, a size of the light transmittance portion of the first BM layer 407 may be greater than a size of the light transmittance portion of the second BM layer 409 aligned with the light-emitting portion. For example, a size of the light transmittance portion of the first BM layer 407 may be smaller than a size of the light transmittance portion of the second BM layer 409 aligned with the light-emitting portion.

The window layer 410 may be disposed on or above the second BM layer 409 to protect the display panel 160 from external impact. For example, the window layer 410 may cover the second BM layer 409.

The first sub-pixel groups 311 (or the first sub-pixels 321, the third sub-pixels 323, and the fifth sub-pixels 325) included in the sub-pixels 310 arranged according to the first example configuration may have a structure illustrated in FIG. 4 or a structure corresponding to the structure illustrated in FIG. 4.

The display 220 may include a pixel layer (e.g., a layer including the circuit layer 401 and/or the light emission layer 402) including a first pixel group (e.g., the first sub-pixel groups 311) and a second pixel group (e.g., the second sub-pixel groups 312). The display 220 may include a light-blocking layer (e.g., a layer including at least one of the color filter layer 405, the first BM layer 407, and/or the second BM layer 409) forming a first light transmittance portion disposed above the first pixel group and having a first width corresponding to the first viewing angle, and a second light transmittance portion disposed above the second pixel group, corresponding to the second viewing angle, and having a second width smaller than the first width.

FIG. 5 is a cross-sectional view taken along line C-D of FIG. 3 according to various embodiments.

Referring to FIG. 5, the second sub-pixel groups 312 (or the second sub-pixels 322, the fourth sub-pixels 324, and the fifth sub-pixels 326) included in the sub-pixels 310 arranged according to the first example configuration may have a structure illustrated in FIG. 5 or a structure corresponding to the structure illustrated in FIG. 5. The second BM layer 409 in the structure illustrated in FIG. 5 may be partially different from the second BM layer 409 in the structure illustrated in FIG. 4.

A circuit layer 401, a light emission layer 402, an encapsulation layer 403, and a touch-sensitive layer 404 illustrated in FIG. 5 may correspond to the circuit layer 401, the light emission layer 402, the encapsulation layer 403, and the touch-sensitive layer 404 illustrated in FIG. 4.

A color filter layer 405 illustrated in FIG. 5 may correspond to the color filter layer 405 illustrated in FIG. 4. For example, a color filter portion 521 may be configured to transmit light having the first color, which is a color of light emitted from a light-emitting portion included in a second sub-pixel 322-1 of the second sub-pixels 322.

A first thickness compensation layer 406, a first BM layer 407, and a second thickness compensation layer 408 illustrated in FIG. 5 may correspond to the first thickness compensation layer 406, the first BM layer 407, and the second thickness compensation layer 408 illustrated in FIG. 4. As a non-limiting example, the second thickness compensation layer 408 may include a layer and another layer. For example, a material included in the layer may be the same as a material included in the first thickness compensation layer 406. For example, a material included in the other layer may be different from the material included in the layer.

The second BM layer 409 may be disposed on or above the second thickness compensation layer 408. The second BM layer 409 may correspond to the BM layer defined in the description of FIG. 3. The second BM layer 409 may include light transmittance portions. For example, the second BM layer 409 may include a light transmittance portion 380, a light transmittance portion 382, a light transmittance portion 384, and a light transmittance portion 386. For example, the second BM layer 409 associated with the second sub-pixel groups 312 (or the second sub-pixels 322, the fourth sub-pixels 324, and the fifth sub-pixels 326) may include the light transmittance portion 382, the light transmittance portion 384, and the light transmittance portion 386. For example, the second sub-pixel 322-1 from among the second sub-pixels 322 may include the light transmittance portion 382. The second BM layer 409 may include a BM portion 542 defining (or surrounding) the light transmittance portions.

The window layer 410 illustrated in FIG. 5 may correspond to the window layer 410 illustrated in FIG. 4.

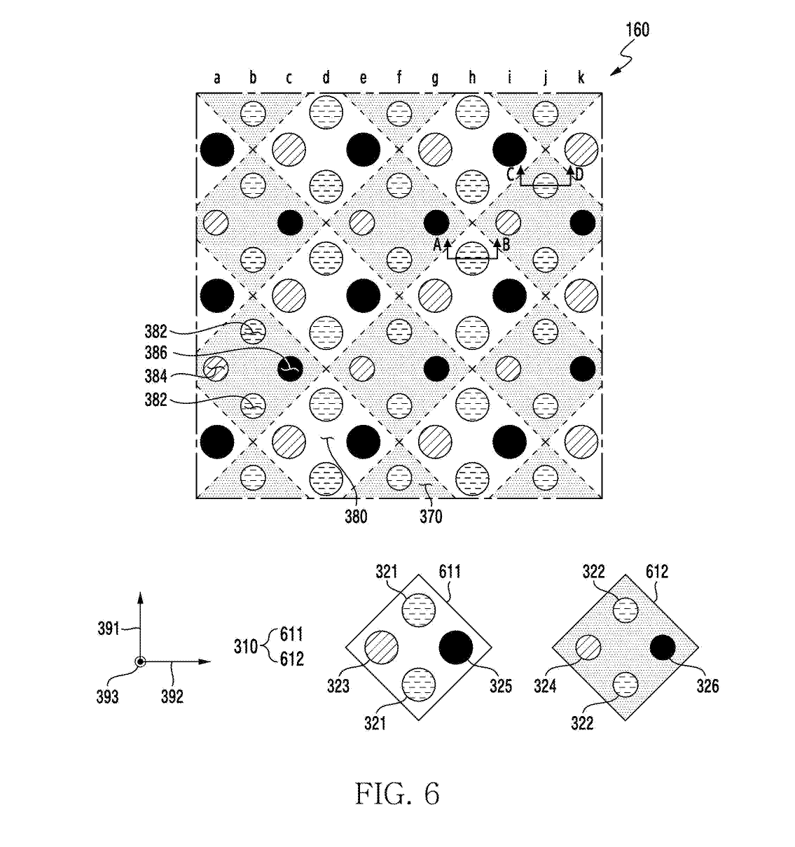

FIG. 6 is a diagram illustrating an example configuration of a display panel including sub-pixels arranged according to various embodiments.

Referring to FIG. 6, the display panel 160 according to the second example configuration may have an arrangement of the sub-pixels 310 different from an arrangement of the sub-pixels 310 included in the display panel 160 according to the example configuration of FIG. 3 (e.g., the display panel 160 according to the first example configuration of FIG. 3) which may be referred to as a “first example configuration” and the example configuration illustrated in FIG. 6 may be referred to as a “second example configuration” for convenience of description, but it will be understood that the disclosure is not limited thereto.

First sub-pixel groups 611 and second sub-pixel groups 612 may be defined in the display panel 160 with respect to a display mode (e.g., the normal display mode and the privacy display mode). As a non-limiting example, the first sub-pixel groups 611 may be used for the normal display mode from among the normal display mode and the privacy display mode. As a non-limiting example, the second sub-pixel groups 612 may be used for both the normal display mode and the privacy display mode.

An arrangement of the sub-pixels 310 included in the display panel 160 according to the second example configuration, which is different from an arrangement of the sub-pixels 310 included in the display panel 160 according to the first example configuration, is described below.

The sub-pixels 310 may be defined by not only a circuit layer (described with reference to FIGS. 4 and 5) and a light emission layer (described with reference to FIGS. 4 and 5) but also the BM layer (or a viewing angle adjustment layer) (or an FOI adjustment layer). The first sub-pixel groups 611 may include first sub-pixels 321 configured to emit light having the first color and included (or positioned) in each of columns (e.g., column d and column h) defined in a vertical direction 391, third sub-pixels 323 configured to emit light having the second color and included in each of columns (e.g., column c, column g, and column k) defined in the vertical direction 391, and fifth sub-pixels 325 configured to emit light having the third color and included in each of columns (e.g., column a, column e, and column i) defined in the vertical direction 391. The second sub-pixel groups 612 may include second sub-pixels 322 configured to emit light having the first color and included in each of columns (e.g., column b, column f, and column j) defined in the vertical direction 391, fourth sub-pixels 324 configured to emit light having the second color and included in columns (e.g., column a, column e, and column i) defined in the vertical direction 391, and sixth sub-pixels 326 configured to emit light having the third color and included in columns (e.g., column c, column g, and column k) defined in the vertical direction 391.

The first sub-pixels 321 may be arranged in the vertical direction 391 within a column. The second sub-pixels 322 may be arranged in the vertical direction 391 within a column. The first sub-pixels 321 within a column may be respectively disposed alongside the second sub-pixels 322 within another column, in a horizontal direction 392.

The third sub-pixels 323 may be arranged in the vertical direction 391 within a column. The sixth sub-pixels 326 may be arranged in the vertical direction 391 within a column. The sixth sub-pixels 326 may alternate with the third sub-pixels 323 in the vertical direction 391 within a column. The third sub-pixels 323 within a column may be respectively disposed alongside the fifth sub-pixels 325 within another column, in the horizontal direction 392. The sixth sub-pixels 326 within a column may be respectively disposed alongside the fourth sub-pixels 324 within another column, in the horizontal direction 392.

The fourth sub-pixels 324 may be arranged in the vertical direction 391, within a column. The fifth sub-pixels 325 may be arranged in the vertical direction 391, within a column. The fifth sub-pixels 325 may alternate with the fourth sub-pixels 324 in the vertical direction 391, within a column.

The description of FIGS. 4 and 5 may be identically or similarly applied to the cross-sections A-B and C-D of FIG. 6.

Referring to the description above, the electronic device 101 may switch a display mode of the display 220 to adjust visibility of the display 220 (or the display panel 160 or an image displayed on the display panel 160). The electronic device 101 may display an image using the first sub-pixel groups 311 and the second sub-pixel groups 312 to provide the normal display mode among the display modes of the display 220. For example, the electronic device 101 may display an image using both the first sub-pixel 321-1 included in the first sub-pixel groups 311 and the second sub-pixel 322-1 included in the second sub-pixel groups 312, to provide the normal display mode.

The electronic device 101 may display an image using the second sub-pixel groups 312 among the first sub-pixel groups 311 and the second sub-pixel groups 312 to provide the privacy display mode among the display modes of the display 220. In order to provide the privacy display mode, the electronic device 101 may refrain from (or bypass, cease, or stop) displaying an image using the first sub-pixel groups 311 and may display an image using the second sub-pixel groups 312. For example, in order to provide the privacy display mode, the electronic device 101 may display an image using the first sub-pixel 321-1 included in the first sub-pixel groups 311 from among the first sub-pixel 321-1 and the second sub-pixel 322-1 included in the second sub-pixel groups 312.

For convenience of description, a sub-pixel (or a wide pixel) having a relatively wide FOI and used to provide the normal display mode is described using the first sub-pixel 321-1. However, the present disclosure is not limited thereto. The following description regarding the first sub-pixel 321-1 may be substantially equally applied to each of sub-pixels included in the first sub-pixel groups 311. In addition, hereinafter, for convenience of description, a sub-pixel (or a narrow pixel) having a relatively narrow FOI and used to provide both the normal display mode and the privacy display mode is described using the second sub-pixel 322-1. However, the present disclosure is not limited thereto. The following description regarding the second sub-pixel 322-1 may be substantially equally applied to each of sub-pixels included in the second sub-pixel groups 312.

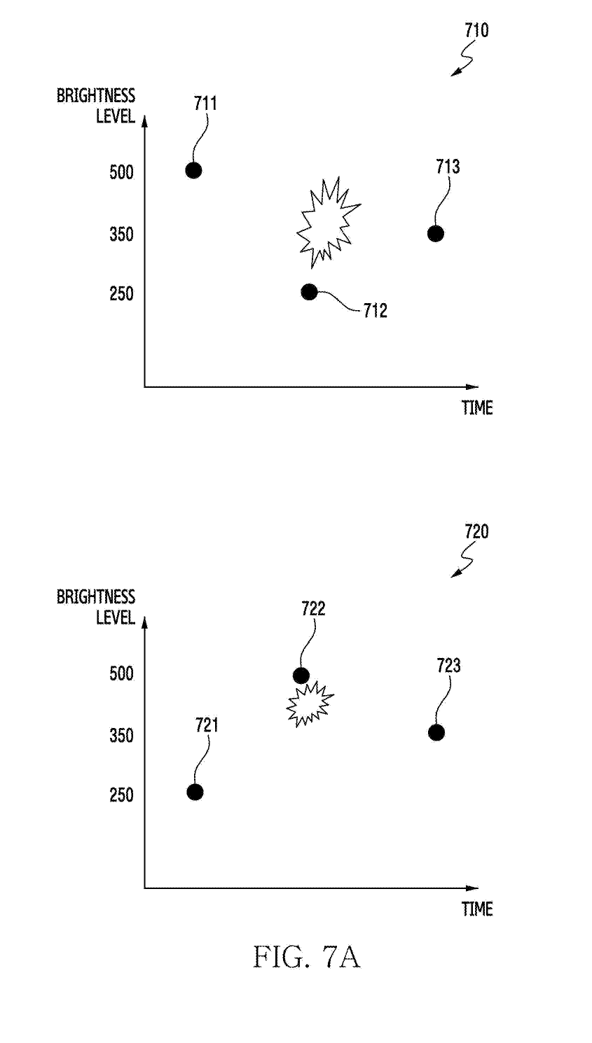

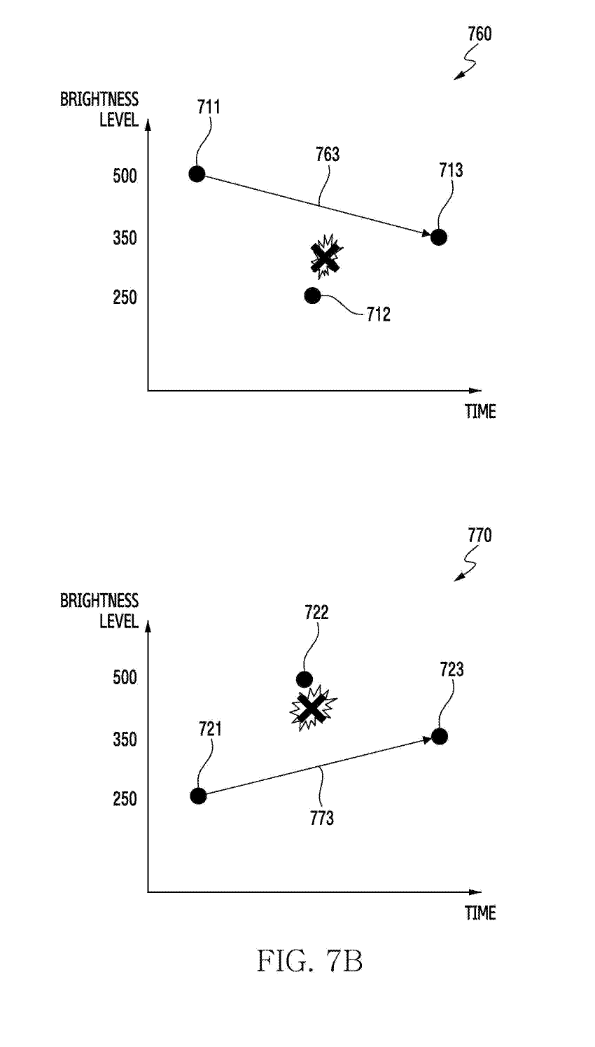

Referring to the description above, the number of sub-pixels used for image display may be changed according to switching of the display mode of the display 220. As a non-limiting example, the number of sub-pixels used for image display in the privacy display mode may be half of the number of sub-pixels used for image display in the normal display mode. As the number of sub-pixels used for image display changes according to the display mode, a brightness level of the display 220 (or the display panel 160 or an image displayed through the display panel 160) viewable (or recognizable) from outside the display 220 (or the display panel 160 or the electronic device 101) may be changed according to switching of the display mode of the display 220. A difference in brightness level caused by switching of the display mode of the display 220 is described in greater detail below with reference to FIG. 7A.

FIG. 7A includes graphs illustrating a difference in brightness level caused in a display when switching a display mode of a display according to various embodiments.

FIG. 7A includes a graph 710 indicating a difference in brightness level caused in the display 220 when the display mode of the display 220 is switched from the normal display mode to the privacy display mode, and a graph 720 indicating a difference in brightness level caused in the display 220 when the display mode of the display 220 is switched from the privacy display mode to the normal display mode.

A horizontal axis of each of the graph 710 and the graph 720 may indicate time, and a vertical axis of each of the graph 710 and the graph 720 may indicate a brightness level (unit: nit) of the display 220 (or the display panel 160 or an image displayed on the display panel 160) viewable from outside the display 220 (or the electronic device 101 or the display panel 160).

The normal display mode may be referred to as a first display mode observable at a first viewing angle. The privacy display mode may be referred to as a second display mode observable at a second viewing angle narrower than the first viewing angle.

Referring to the graph 710, a first point 711 may indicate a brightness level when the normal display mode is provided. As a non-limiting example, at the first point 711, a brightness level of the display 220 may be about 500 nits. When the display mode of the display 220 is switched from the normal display mode to the privacy display mode, the brightness level of the display 220 may be changed from the first point 711 to a second point 712.

As a non-limiting example, at the second point 712, a brightness level of the display 220 may be about 250 nits. This may be because the first sub-pixel 321-1 among the first sub-pixel 321-1 and the second sub-pixel 322-1 is turned off as the display mode is switched from the normal display mode to the privacy display mode. In other words, in the privacy display mode, since the second sub-pixel 322-1 among the first sub-pixel 321-1 and the second sub-pixel 322-1 is used for image display, the brightness level of the display 220 may be reduced to about 250 nits, which is half of about 500 nits.

The electronic device 101 may increase a luminance value (or a display brightness value (DBV)) to compensate for a decrease in a brightness level caused in the privacy display mode. For example, the luminance value may indicate a brightness level set with respect to the display 220 (or the display panel 160). According to the compensation in the privacy display mode, the brightness level of the display 220 may be changed from the second point 712 to a third point 713. As a non-limiting example, at the third point 713, the brightness level of the display 220 may be about 350 nits. In this case, a sub-pixel to be targeted for the compensation may be the second sub-pixel 322-1 among the first sub-pixel 321-1 and the second sub-pixel 322-1.

Referring to the graph 710, a difference may be caused between a timing at which the display mode is switched from the normal display mode to the privacy display mode and a timing at which the compensation is performed. For example, the difference may be caused by asynchronization (or misalignment) between the timing at which the display mode is switched from the normal display mode to the privacy display mode and the timing at which the compensation is performed. For example, the difference may be caused because switching of a data voltages applied to each of sub-pixels of the display panel 160 within a short time (e.g., 1 frame) is impossible according to a step efficiency (SE) characteristic. As the difference between the timings is caused, a user viewing the display 220 may recognize a difference in brightness level according to switching of the display mode. The difference in brightness level may be referred to as flickering.

The flickering may be caused by not only the switching of the display mode from the normal display mode to the privacy display mode illustrated in the graph 710, but also the switching of the display mode from the privacy display mode to the normal display mode. The flickering caused by the switching of the display mode from the privacy display mode to the normal display mode is described with reference to the graph 720.

Referring to the graph 720, a first point 721 may indicate a brightness level when the privacy display mode is provided. As a non-limiting example, at the first point 721, a brightness level of the display 220 may be about 250 nits. When the display mode of the display 220 is switched from the privacy display mode to the normal display mode, the brightness level of the display 220 may be changed from the first point 721 to a second point 722.

As a non-limiting example, at the second point 722, the brightness level of the display 220 may be about 500 nits. This may be because the first sub-pixel 321-1 is turned on again as the display mode is switched from the privacy display mode to the normal display mode. In other words, in the normal display mode, since both the first sub-pixel 321-1 and the second sub-pixel 322-1 are used for image display, the brightness level of the display 220 may be increased from about 250 nits to about 500 nits corresponding to two times.

The electronic device 101 may decrease a luminance value (or a display brightness value (DBV)) to readjust a compensated brightness level for the privacy display mode. According to the readjustment of the compensation in the normal display mode, the brightness level of the display 220 may be changed from the second point 722 to a third point 723. As a non-limiting example, at the third point 723, the brightness level of the display 220 may be about 350 nits. In this case, a sub-pixel to be targeted for the compensation may be the second sub-pixel 322-1 among the first sub-pixel 321-1 and the second sub-pixel 322-1.

Also in the graph 720, similarly to the graph 710, a user viewing the display 220 may recognize a difference in brightness level according to switching of the display mode.

Referring to FIG. 7A, an operation in which a brightness level of the display 220 is changed as the display mode is switched from the normal display mode to the privacy display mode is described, but the present disclosure is not limited thereto. For example, when an illuminance level identified through an illuminance sensor included in the electronic device 101 exceeds a threshold illuminance level (e.g., when the electronic device 101 is directly exposed to sunlight), the electronic device 101 may refrain from, bypass, or block switching of the display mode from the normal display mode to the privacy display mode. For example, while the illuminance level exceeding the threshold illuminance level is identified, since it is difficult to maintain a brightness level of the display 220 (or to reduce a difference between the brightness level of the display 220 in the normal display mode and the brightness level of the display 220 in the privacy display mode) using only the second sub-pixel groups 312 among the first sub-pixel groups 311 and/or the second sub-pixel groups 312 in the privacy display mode, the electronic device 101 (or the at least one processor 210) may refrain from, bypass, or block switching to the privacy display mode.

In order to reduce recognition of the difference in brightness level according to switching of the display mode described in FIG. 7A, the electronic device 101 may perform a smooth switching of the display mode. The smooth switching of the display mode is described in greater detail below with reference to FIG. 7B.

FIG. 7B includes graphs illustrating a brightness level of a display, gradually changed while switching a display mode of a display according to various embodiments.

FIG. 7B includes a graph 760 indicating a brightness level of the display 220 gradually changed when the display mode of the display 220 is switched from the normal display mode to the privacy display mode, and a graph 770 indicating a brightness level of the display 220 gradually changed when the display mode of the display 220 is switched from the privacy display mode to the normal display mode.

A horizontal axis of each of the graphs 760 and 770 may indicate time, and a vertical axis of each of the graphs 760 and 770 may indicate a brightness level (unit: nit) of the display 220 (or the display panel 160 or an image displayed on the display panel 160) viewable from outside the display 220 (or the electronic device 101 or the display panel 160).

Referring to the graph 760, a first point 711 may indicate a brightness level when the normal display mode is provided. As a non-limiting example, at the first point 711, the brightness level of the display 220 may be about 500 nits. A third point 713 may indicate a brightness level when the privacy display mode is provided. As a non-limiting example, at the third point 713, the brightness level of the display 220 may be about 350 nits.

In the graph 760 of FIG. 7B, the electronic device 101 may perform a smooth switching from the normal display mode to the privacy display mode. For example, the electronic device 101 may perform the smooth switching by gradually changing (or decreasing) a grayscale level associated with sub-pixels (e.g., the first sub-pixel 321-1) of the first sub-pixel groups 311 among the sub-pixels of the display panel 160. For example, the electronic device 101 may perform the smooth switching by gradually changing (or increasing) a luminance value associated with sub-pixels (e.g., the second sub-pixel 322-1) of the second sub-pixel groups 312 among the sub-pixels of the display panel 160. Alternatively, for example, unlike the graph 710 of FIG. 7A, in which the display mode is switched from the normal display mode to the privacy display mode at a timing indicated by the second point 712, the electronic device 101 may gradually change the grayscale level and/or the luminance value during a time interval between a timing indicated by the first point 711 and a timing indicated by the third point 713. As a non-limiting example, unlike the graph 710 of FIG. 7A, in the graph 760 of FIG. 7B, a switching to the privacy display mode may be completed at a timing indicated by the third point 713. For example, the time interval between the timing indicated by the first point 711 and the timing indicated by the third point 713 may be referred to as a mode for a transition of the display mode of the display 220 (or a transition display mode). For example, the display mode of the display 220 may further include the normal display mode, the privacy display mode, and the transition mode between the normal display mode and the privacy display mode. For example, unlike illustrated in the graph 760 of FIG. 7B, the switching to the privacy display mode may also be completed at a timing indicated by the second point 712 of the graph 710 of FIG. 7A. For example, a length of the time interval may be adjusted. For example, the electronic device 101 may adjust a period for gradually changing the grayscale level and/or the luminance value during the time interval. For example, the period may be referred to as the number or a frequency of gradual changes during the time interval.

Referring to the graph 760, a line 763 indicates a brightness level of the display 220 gradually changed according to performing the smooth switching. Referring to the line 763, the brightness level of the display 220 may be gradually decreased during a time interval between a timing indicated by the first point 711 and a timing indicated by the third point 713. For example, the brightness level of the display 220 may be gradually decreased from about 500 nits to about 350 nits. As the brightness level of the display 220 is gradually decreased, a difference in brightness level according to the switching of the display mode may be relatively less recognized by a user viewing the display 220. In other words, a possibility that flickering may be caused in the display 220 may be reduced.

The smooth switching of the display mode may be performed not only in the switching of the display mode from the normal display mode to the privacy display mode illustrated in the graph 760, but also in the switching of the display mode from the privacy display mode to the normal display mode. The smooth switching of the display mode from the privacy display mode to the normal display mode is described with reference to the graph 770.

Referring to the graph 770, a first point 721 may indicate a brightness level when the privacy display mode is provided. As a non-limiting example, at the first point 721, the brightness level of the display 220 may be about 250 nits. A third point 723 may indicate a brightness level when the normal display mode is provided. As a non-limiting example, at the third point 723, the brightness level of the display 220 may be about 350 nits.

In the graph 770 of FIG. 7B, the electronic device 101 may perform a smooth switching from the privacy display mode to the normal display mode. For example, the electronic device 101 may perform the smooth switching by gradually changing (or increasing) a grayscale level associated with sub-pixels (e.g., the first sub-pixel 321-1) of the first sub-pixel groups 311 among sub-pixels of the display panel 160. Alternatively, for example, the electronic device 101 may perform the smooth switching by gradually changing (or decreasing) a luminance value associated with sub-pixels (e.g., the second sub-pixel 322-1) of the second sub-pixel groups 312 among the sub-pixels of the display panel 160. Alternatively, for example, unlike the graph 720 of FIG. 7A in which the display mode is switched from the normal display mode to the privacy display mode at a timing indicated by the second point 722, the electronic device 101 may gradually change the grayscale level and/or the luminance value during a time interval between a timing indicated by the first point 721 and a timing indicated by the third point 723. As a non-limiting example, unlike the graph 720 of FIG. 7A, in the graph 770 of FIG. 7B, the switching to the privacy display mode may be completed at a timing indicated by the third point 723. However, the present disclosure is not limited thereto. For example, unlike illustrated in the graph 770 of FIG. 7B, the switching to the privacy display mode may be completed at a timing indicated by the second point 722 of the graph 720 of FIG. 7A. For example, a length of the time interval may be adjusted. Alternatively, for example, the electronic device 101 may adjust a period of gradually changing the grayscale level and/or the luminance value during the time interval. For example, the period may be referred to as the number or a frequency of gradual changes during the time interval.

Referring to the graph 770, a line 773 indicates a brightness level of the display 220 gradually changed according to performing the smooth switching. Referring to the line 773, the brightness level of the display 220 may be gradually increased during a time interval between a timing indicated by the first point 721 and a timing indicated by the third point 723. For example, the brightness level of the display 220 may be gradually increased from about 250 nits to about 350 nits. As the brightness level of the display 220 is gradually increased, a difference in brightness level according to the switching of the display mode may be relatively less recognized by a user viewing the display 220. In other words, a possibility that flickering may be caused in the display 220 may be reduced.

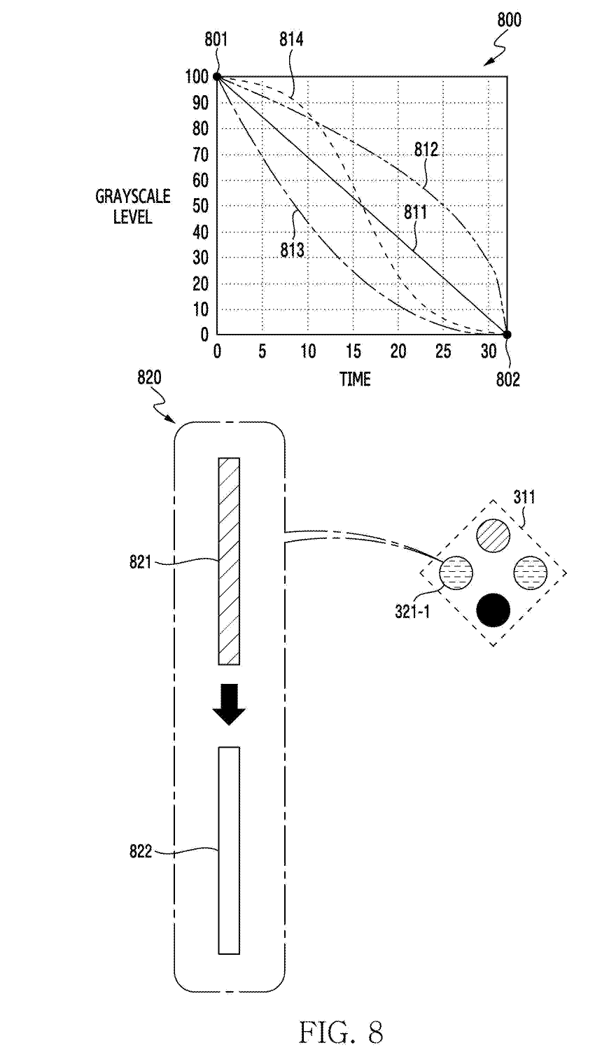

A method of gradually changing a grayscale level associated with the first sub-pixel 321-1 when switching the display mode of the display 220 is described in greater detail below with reference to FIG. 8.

FIG. 8 includes a diagram and a graph illustrating an example method of gradually changing a grayscale level to gradually change a brightness level provided through a first sub-pixel used for a normal display mode according to various embodiments.

FIG. 8 illustrates a graph 800 in which a grayscale level associated with the first sub-pixel 321-1 is gradually (it will be understood that as used herein the term “gradually” may indicate a rate lower than a specified rate or threshold rate) decreased while the display mode of the display 220 is switched, and a state 820 in which a brightness level provided through the first sub-pixel 321-1 is gradually decreased according to the gradual decrease of the grayscale level.

For example, a grayscale level associated with the first sub-pixel 321-1 may be used to determine a data voltage to be applied to the first sub-pixel 321-1. For example, the data voltage to be applied to the first sub-pixel 321-1 may be determined based on the grayscale level corresponding to a portion of an image to be displayed through the first sub-pixel 321-1 and a luminance value set with respect to the display 220 (or the display panel 160 or the electronic device 101).

For example, at least one processor 210 may provide (or transmit) an image (or image data) to be displayed through the display 220 (or the display panel 160) to the display 220 (or the display driver circuitry 221). The image provided from at least one processor 210 to the display driver circuitry 221 may include a grayscale value corresponding to a portion of an image to be displayed at each sub-pixel (or each pixel). The grayscale value corresponding to the portion of the image provided from at least one processor 210 to the display driver circuitry 221 may also be referred to as a grayscale level. For example, the display driver circuitry 221 may identify a grayscale level corresponding to the grayscale value, and apply, to a corresponding sub-pixel (e.g., the first sub-pixel 321-1), a data voltage determined based on the identified grayscale level.

In the above example, the display driver circuitry 221 may receive commands for adjusting a grayscale level from at least one processor 210, during a time interval in which the display mode is switched. As a non-limiting example, the time interval in which the display mode is switched may be a time interval between a first timing at which an event for switching the display mode is identified by at least one processor 210 and a second timing at which the switching of the display mode is completed. As a non-limiting example, the event may include a reception (or obtaining or identification) of an input for switching the display mode. For example, the second timing may be a timing at which the switching to the privacy display mode is completed or the privacy display mode is provided when the switching of the display mode is switching from the normal display mode to the privacy display mode. For example, each of the commands may be used to adjust a grayscale level, independently of a grayscale value of an image provided from at least one processor 210. For example, the display driver circuitry 221 may identify a grayscale level for determining a data voltage to be applied to the first sub-pixel 321-1 from a grayscale value of a portion of an image corresponding to the first sub-pixel 321-1, in response to the received commands. The identified grayscale level may be gradually changed (or decreased or increased) according to the commands. For example, as the grayscale level is gradually changed, a data voltage to be applied to the first sub-pixel 321-1 may be gradually changed (or decreased or increased). In the example of FIG. 8, as the grayscale level is gradually decreased, the data voltage to be applied to the first sub-pixel 321-1 may be gradually decreased.

When the switching of the display mode is switching from the normal display mode to the privacy display mode, the gradual decrease of the grayscale level associated with the first sub-pixel 321-1 is described with reference to the graph 800.

A horizontal axis of the graph 800 indicates time (unit: frame), and a vertical axis of the graph 800 indicates a ratio (unit: percent (%)) of a grayscale level with respect to a grayscale value. In the graph 800, for convenience of description, a grayscale value of a portion corresponding to the first sub-pixel 321-1 of an image received from at least one processor 210 may be 255G. In other words, when the ratio is 100%, the grayscale level may be 255G, when the ratio is 50%, the grayscale level may be 127G, and when the ratio is 0%, the grayscale level may be 0G.

Referring to the graph 800, at a first point 801, the normal display mode among the display modes of the display 220 may be provided. For example, the display driver circuitry 221 may display an image using both the first sub-pixel 321-1 and the second sub-pixel 322-1. With respect to the first point 801, the display driver circuitry 221 may determine (or generate) a data voltage to be applied to the first sub-pixel 321-1. For example, the display driver circuitry 221 may identify a grayscale level to be used for determining a data voltage to be applied to the first sub-pixel 321-1 as 255G, according to a ratio of 100%.

Referring to the graph 800, at a second point 802, the privacy display mode among the display modes of the display 220 may be provided. For example, the display driver circuitry 221 may display an image using the second sub-pixel 322-1 among the first sub-pixel 321-1 and the second sub-pixel 322-1. With respect to the second point 802, the display driver circuitry 221 may determine (or generate) a data voltage to be applied to the first sub-pixel 321-1. For example, the display driver circuitry 221 may identify a grayscale level to be used for determining a data voltage to be applied to the first sub-pixel 321-1 as 0G, according to a ratio of 0%.

For example, the display driver circuitry 221 may gradually decrease a grayscale level during a time interval to gradually decrease a data voltage to be applied to the first sub-pixel 321-1. For example, the time interval may be defined as a time interval between a first timing at which the event is identified by at least one processor 210 and a second timing at which the switching to the privacy display mode is completed. In the graph 800, the first timing may be substantially the same as a timing indicated by the first point 801, and the second timing may be substantially the same as a timing indicated by the second point 802. As a non-limiting example, a length of the time interval may be defined by 32 frames. For example, each of the frames may be defined by a vertical synchronization signal generated (or transmitted) by the display 220. For example, a length of the frames may correspond to a period at which the vertical synchronization signal is generated (or transmitted). The gradual decrease of the grayscale level is described with reference to lines 811, 812, 813, and 814 of the graph 800.

Each of the lines 811, 812, 813, and 814 may indicate a grayscale level gradually decreased from a first grayscale level (e.g., 255G) indicated by the first point 801 to a second grayscale level (e.g., 0G) indicated by the second point 802.

For example, the line 811 may be referred to as a linear curve. Referring to the line 811, the display driver circuitry 221 may uniformly decrease, over time, the grayscale level associated with the first sub-pixel 321-1 from the first grayscale level to the second grayscale level, within the time interval. As a non-limiting example, a rate of change (or a decrease amount) of the grayscale level according to the line 811 may be 8G per frame. For example, the display driver circuitry 221 may gradually decrease the grayscale level, within the time interval (or 32 frames), in the order of 255G, 247G, 239G, ..., 8G, and 0G.

For example, the line 812 may be referred to as an inverted-gamma curve. Referring to the line 812, the display driver circuitry 221 may non-uniformly decrease, over time, the grayscale level associated with the first sub-pixel 321-1 from the first grayscale level to the second grayscale level, within the time interval. For example, the display driver circuitry 221 may identify the grayscale level as a third grayscale level decreased from the first grayscale level, at a third timing next to 16 frames from the first timing. As a non-limiting example, the third grayscale level may be 192G, according to a ratio of about 75%. The display driver circuitry 221 may identify the grayscale level as the second grayscale level, at the second timing next to 16 frames from the third timing.

For example, the line 813 may be referred to as a gamma curve. Referring to the line 813, the display driver circuitry 221 may non-uniformly decrease, over time, the grayscale level associated with the first sub-pixel 321-1 from the first grayscale level to the second grayscale level, within the time interval. For example, the display driver circuitry 221 may identify the grayscale level as a third grayscale level decreased from the first grayscale level, at a third timing next to 16 frames from the first timing. As a non-limiting example, the third grayscale level may be 64G, according to a ratio of about 25%. The display driver circuitry 221 may identify the grayscale level as the second grayscale level, at the second timing next to 16 frames from the third timing. In other words, a rate of change (or a decrease amount) of the grayscale level according to the line 813 may be opposite to a rate of change (or a decrease amount) of the grayscale level according to the line 812.

For example, the line 814 may be referred to as an S curve. Referring to the line 814, the display driver circuitry 221 may non-uniformly decrease, over time, the grayscale level associated with the first sub-pixel 321-1 from the first grayscale level to the second grayscale level within the time interval. For example, the display driver circuitry 221 may identify the grayscale level as a third grayscale level decreased from the first grayscale level, at a third timing next to 8 frames from the first timing. As a non-limiting example, the third grayscale level may be about 239G, according to a ratio of about 90%. For example, the display driver circuitry 221 may identify the grayscale level as a fourth grayscale level decreased from the third grayscale level, at a fourth timing next to 8 frames from the third timing. As a non-limiting example, the fourth grayscale level may be about 128G, according to a ratio of about 50%. For example, the display driver circuitry 221 may identify the grayscale level as a fifth grayscale level decreased from the fourth grayscale level, at a fifth timing next to 8 frames from the fourth timing. As a non-limiting example, the fifth grayscale level may be about 26G, according to a ratio of about 10%. In other words, according to the line 814, the grayscale level may be decreased by a first value within a first partial time including the first timing, and may be decreased by the first value within a second partial time including the second timing and having the same length as the first partial time. In addition, the grayscale level may be decreased by a second value different from the first value, within a third partial time between the first partial time and the second partial time.

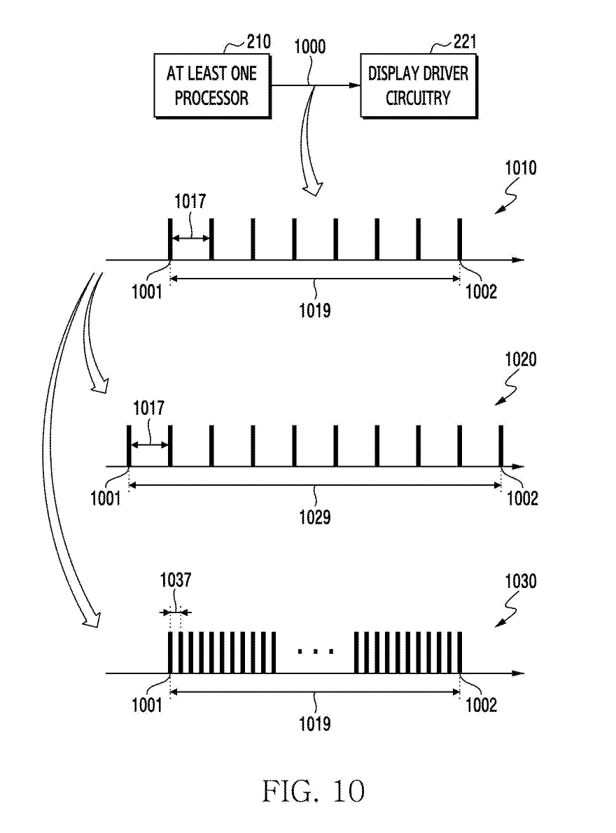

A rate of change (or a decrease amount) of a grayscale level according to the lines 811, 812, 813, and 814 may be indicated by commands transmitted from at least one processor 210 to the display driver circuitry 221. For example, at least one processor 210 may identify a rate of change (or a decrease amount) of the grayscale level using an identified curve among curves stored in the memory 230. For example, at least one processor 210 may transmit, to the display driver circuitry 221, a command indicating the identified rate of change (or a decrease amount) of the grayscale level (or a grayscale level to be changed). Details regarding the commands are described in greater detail below with reference to FIG. 10.

Referring to the state 820, a gradual decrease in a brightness level provided through the first sub-pixel 321-1 according to a gradual decrease in a grayscale level associated with the first sub-pixel 321-1 is illustrated. The brightness level provided through the first sub-pixel 321-1 may indicate a brightness level of the first sub-pixel 321-1 (or a portion of an image displayed through the first sub-pixel 321-1) viewable (or recognizable) from outside the display 220 (or the display panel 160 or the electronic device 101).

Referring to an example 821 of the state 820, a brightness level provided through the first sub-pixel 321-1 to which a first data voltage according to the first grayscale level is applied may be a first brightness level. Referring to an example 822 of the state 820, a brightness level provided through the first sub-pixel 321-1 to which a second data voltage according to the second grayscale level is applied may be a second brightness level. For example, the second brightness level may be lower than the first brightness level. For example, a voltage level of the second data voltage may be lower than a voltage level of the first data voltage. As a non-limiting example, the second grayscale level may be a grayscale level indicating a black color. The second brightness level may be referred to as a defined brightness level to be provided when emission through the first sub-pixel 321-1 is refrained or light indicating the black color is emitted through the first sub-pixel 321-1.

Although not illustrated in the state 820, a brightness level provided through the first sub-pixel 321-1 may be gradually decreased from the first brightness level to the second brightness level during a time interval in which the normal display mode is switched to the privacy display mode. A rate of change (or a decrease amount) at which the brightness level provided through the first sub-pixel 321-1 is gradually decreased may be determined according to a curve indicating a rate of change (or a decrease amount) of a gradual decrease of a grayscale level associated with the first sub-pixel 321-1.

Referring to the lines 811, 812, 813, and 814 of the graph 800, a grayscale level of the first sub-pixel 321-1 gradually changed while the display mode of the display 220 is switched to the privacy display mode, a DBV table for compensating a luminance value associated with the second sub-pixel 322-1, luminance curves (e.g., the lines 811, 812, 813, and 814) for compensating a brightness level of the display 220, and/or the number (e.g., 32) of frames between a timing indicated by the first point 801 and a timing indicated by the second point 802 (or a frequency defined from the timing indicated by the first point 801 and the timing indicated by the second point 802) are described, but embodiments of the present disclosure are not limited thereto. For example, at least one of the grayscale level of the first sub-pixel 321-1 gradually changed, the DBV table for compensating a luminance value associated with the second sub-pixel 322-1, the luminance curves (e.g., the lines 811, 812, 813, and 814) for compensating a brightness level of the display 220, and/or the number of frames (e.g., 32) between the timing indicated by the first point 801 and the timing indicated by the second point 802 (or the frequency defined from the timing indicated by the first point 801 and the timing indicated by the second point 802) may be changed or determined based on a burn-in state of the second sub-pixel 322-1 (e.g., a degree to which the second subpixel 322-1 is burned).

Referring to FIG. 8, although an example in which the display driver circuitry 221 gradually adjusts a grayscale level to be applied to the first sub-pixel 321-1 while the switching of the display mode of the display 220 is performed is described, the present disclosure is not limited thereto. For example, the display driver circuitry 221 may gradually adjust the number of sub-pixels of the first sub-pixel groups 311 used for displaying an image. The number of sub-pixels used for displaying an image may be referred to as on pixel ratio (OPR). For example, the display driver circuitry 221 may control the first sub-pixel groups 311 to emit light according to a grayscale value of an image received from at least one processor 210. As illustrated in the graph 800 of FIG. 8, substantially identically to adjusting a ratio of a grayscale level with respect to a grayscale value, the display driver circuitry 221 may gradually adjust the number of sub-pixels, among the sub-pixels of the first sub-pixel groups 311, used for displaying an image, according to the ratio.

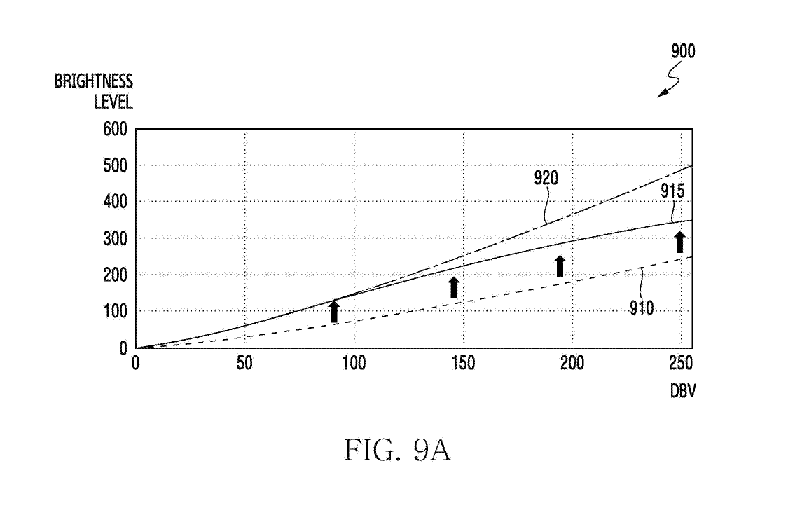

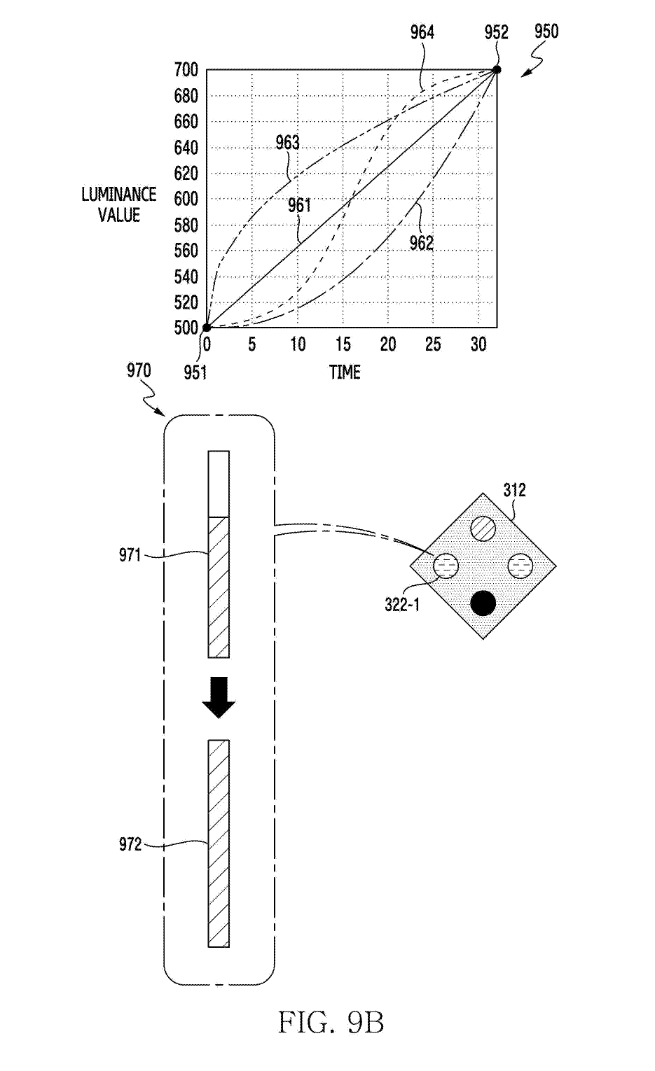

Referring to FIG. 8, the display driver circuitry 221 may gradually adjust a brightness level provided through the first sub-pixel 321-1, by gradually adjusting a grayscale level to be applied to the first sub-pixel 321-1 from a grayscale value obtained from at least one processor 210. As the brightness level provided through the first sub-pixel 321-1 is gradually adjusted, a brightness level viewable from outside the display 220 may be decreased in the privacy display mode of the display 220. Accordingly, the display driver circuitry 221 may adjust (or increase) a brightness level provided through the second sub-pixel 322-1 to at least partially compensate for the decrease in the brightness level provided through the first sub-pixel 321-1. The brightness level provided through the second sub-pixel 322-1 may be determined by adjusting (or increasing) a luminance value associated with the second sub-pixel 322-1. A method for adjusting the brightness level provided through the second sub-pixel 322-1 is described in greater detail below with reference to FIGS. 9A and 9B.

FIG. 9A is a graph indicating a brightness level according to a luminance value in a display mode of a display according to various embodiments.

FIG. 9A is a graph 900 indicating a brightness level of the display 220 (or the display panel 160, or an image displayed through the display panel 160) according to a luminance value in the display mode of the display 220. A horizontal axis of the graph 900 indicates a display brightness value (DBV), and a vertical axis of the graph 900 indicates a brightness level (unit: nit). In the present disclosure, the DBV may indicate a luminance set with respect to the electronic device 101 (or the display 220 or the display panel 160). As a non-limiting example, the DBV may be defined as a range (e.g., 0 to 255) substantially corresponding to a grayscale level (or a grayscale value).

Referring to the graph 900, a first line 910 indicating a brightness level according to the DBV in the privacy display mode among the display modes of the display 220, a second line 920 indicating a brightness level according to the DBV in the normal display mode among the display modes, and a third line 915 indicating a brightness level according to the DBV in the privacy display mode based on compensation of a brightness level provided through the second sub-pixel 322-1 are illustrated.

Referring to the first line 910, a brightness level may have a level between 0 nit and about 250 nits, according to the DBV. As a non-limiting example, a brightness level indicated by the first line 910 may be 0 nit when the DBV is 0. As a non-limiting example, the brightness level indicated by the first line 910 may be about 250 nits when the DBV is 255. For example, the brightness level indicated by the first line 910 may be a brightness level provided through the second sub-pixel 322-1 among the first sub-pixel 321-1 and the second sub-pixel 322-1 from among the sub-pixels of the display panel 160. In other words, for displaying an image in the privacy display mode, the second sub-pixel 322-1 may emit light, and the first sub-pixel 321-1 may not emit light. As a non-limiting example, when the DBV is 255, since the brightness level provided through the second sub-pixel 322-1 is about 500 nits and the brightness level provided through the first sub-pixel 321-1 is about 0 nit, the brightness level of the display 220 may be about 250 nits.

Referring to the second line 920, a brightness level may have a level between 0 nit and about 500 nits, according to the DBV. As a non-limiting example, the brightness level indicated by the second line 920 may be 0 nit when the DBV is 0. As a non-limiting example, the brightness level indicated by the second line 920 may be about 500 nits when the DBV is 255. For example, the brightness level indicated by the second line 920 may be a brightness level provided through all (e.g., the first sub-pixel 321-1 and the second sub-pixel 322-1) of sub-pixels of the display panel 160. In other words, for displaying an image in the normal display mode, both the first sub-pixel 321-1 and the second sub-pixel 322-1 may emit light. As a non-limiting example, when the DBV is 255, since the brightness level provided through the second sub-pixel 322-1 is about 500 nits and the brightness level provided through the first sub-pixel 321-1 is about 500 nits, the brightness level of the display 220 may be about 500 nits.

Referring to the first line 910 and the second line 920, a brightness level of the display 220 may be decreased by about 1/2, according to switching of the display mode of the display 220 from the normal display mode to the privacy display mode. Since the brightness level of the display 220 is decreased according to the switching of the display mode of the display 220 without any change in illuminance outside the electronic device 101, usability may be reduced when the brightness level is decreased under the same illuminance condition (or illuminance value). In addition, due to physical limitations such as an optical characteristic of sub-pixel, it may be impossible to operate a brightness level according to the DBV in the privacy display mode of the display 220 to be substantially identical to a brightness level according to the DBV in the normal display mode, or it may cause problems in current consumption, heat generation, or lifetime of sub-pixel. Therefore, instead of the first line 910 indicating the brightness level according to the DBV in the privacy display mode, a third line 915 in which a brightness level provided through the second sub-pixel 322-1 is adjusted may be used.

Referring to the third line 915, a brightness level may have a level between 0 nit and about 350 nit, according to the DBV. As a non-limiting example, a brightness level indicated by the third line 915 may be 0 nit when the DBV is 0. As a non-limiting example, the brightness level indicated by the third line 915 may be about 350 nit when the DBV is 255. As a non-limiting example, the brightness level indicated by the third line 915 may be substantially similar to the brightness level indicated by the second line 920, within a range of the DBV between 0 and 100. Thereafter, a rate of change (or an increase amount) of the brightness level indicated by the third line 915 may be lower than that of the brightness level indicated by the second line 920, and higher than that of the brightness level indicated by the first line 910. However, embodiments of the present disclosure are not limited thereto. For example, within a range of the DBV between 100 and 255, a rate of change (or an increase amount) of the brightness level indicated by the third line 915 may be (substantially) identical to that of the brightness level indicated by the first line 910. For example, the brightness level indicated by the third line 915 may be a brightness level provided through the second sub-pixel 322-1 among the first subpixels 321-1 and the second subpixel 322- 1 from among sub-pixels of the display panel 160. In this case, the brightness level provided through the second sub-pixel 322-1 at the third line 915 may be higher than the brightness level provided through the second sub-pixel 322-1 at the first line 910. As a non-limiting example, when the DBV is 255, since the brightness level provided through the second sub-pixel 322-1 is about 700 nit and the brightness level provided through the first sub-pixel 321-1 is about 0 nit, the brightness level of the display 220 may be about 350 nit.

The first line 910, the second line 920, and the third line 915 illustrated in FIG. 9A are merely examples for convenience of description, and the present disclosure is not limited thereto. For example, a rate of change (or an increase amount) of the brightness level indicated by the third line 915 may be set differently from the third line 915 illustrated in FIG. 9A. In other words, a slope (or shape, or curve) of the third line 915 indicating a rate of change (or an increase amount) of the brightness level indicated by the third line 915 may be changed.

The third line 915 illustrated in FIG. 9A may be determined according to a gradual change (or increase) in the brightness level provided through the second sub-pixel 322-1. The gradual change in the brightness level provided through the second sub-pixel 322-1 is described in greater detail below with reference to FIG. 9B.

FIG. 9B includes a diagram and a graph illustrating an example method of gradually changing a luminance value to gradually change a brightness level provided through a second sub-pixel used for both a normal display mode and a privacy display mode according to various embodiments.

FIG. 9B is a graph 950 in which a luminance value associated with the second sub-pixel 322-1 is gradually increased while the display mode of the display 220 is switched, and a state 970 in which a brightness level provided through the second sub-pixel 322-1 is gradually increased according to the gradual increase of the luminance value.

For example, a luminance value associated with the second sub-pixel 322-1 may be used to determine a data voltage to be applied to the second sub-pixel 322-1. For example, the data voltage to be applied to the second sub-pixel 322-1 may be determined based on a grayscale level corresponding to a portion of an image to be displayed through the second sub-pixel 322-1 and a luminance value set with respect to the display 220 (or the display panel 160, or the electronic device 101). For example, the luminance value may be defined according to the DBV. For example, the luminance value may indicate a brightness level to be provided (or expected to be displayed, or calculated to be displayed), according to the DBV.

For example, at least one processor 210 may provide (or transmit) to the display 220 (or the display driver circuitry 221) an image (or image data) to be displayed through the display 220 (or the display panel 160). The image provided from at least one processor 210 to the display driver circuitry 221 may include a grayscale value corresponding to a portion of an image to be displayed at each sub-pixel (or each pixel). The grayscale value corresponding to the portion of the image provided from at least one processor 210 to the display driver circuitry 221 may also be referred to as a grayscale level. For example, the display driver circuitry 221 may identify a grayscale level corresponding to the grayscale value, and apply, to a corresponding sub-pixel (e.g., the second sub-pixel 322-1), a data voltage determined based on the identified grayscale level.

In the above example, the display driver circuitry 221 may receive, from at least one processor 210, commands for adjusting a luminance value during a time interval in which the display mode is switched. As a non-limiting example, the time interval in which the display mode is switched may be a time interval between a first timing at which an event for switching the display mode is identified by at least one processor 210 and a second timing at which the switching of the display mode is completed. As a non-limiting example, the event may include receiving (or obtaining, or identifying) an input for switching the display mode. For example, the second timing may be a timing at which the switching to the privacy display mode is completed or the privacy display mode is provided, when the switching of the display mode is a switching from the normal display mode to the privacy display mode. For example, each of the commands may be used to adjust a luminance value, independently from a luminance value set with respect to the electronic device 101 (or the display 220, or the display panel 160). For example, the display driver circuitry 221 may identify a luminance value for determining a data voltage to be applied to the second sub-pixel 322-1, in response to the received commands. The identified luminance value may be gradually changed (or decreased, or increased) according to the commands. As the luminance value is gradually changed, a data voltage to be applied to the second sub-pixel 322-1 may be gradually changed (or decreased, or increased). In the example of FIG. 9B, as the luminance value is gradually increased, the data voltage to be applied to the second sub-pixel 322-1 may be gradually increased.

When the switching of the display mode is a switching from the normal display mode to the privacy display mode, a gradual increase in the luminance value associated with the second sub-pixel 322-1 is described with reference to the graph 950.

A horizontal axis of the graph 950 indicates time (unit: frame), and a vertical axis of the graph 950 indicates a luminance value (unit: nit). In the graph 950, for convenience of explanation, a grayscale value corresponding to a portion of an image received from at least one processor 210 corresponding to the second sub-pixel 322-1 may be 255G. For convenience of explanation, the DBV set with respect to the second sub-pixel 322-1 may be 255. For example, the luminance value may be defined as a brightness level to be provided according to the set DBV (e.g., 255).

Referring to the graph 950, at a first point 951, the normal display mode among the display modes of the display 220 may be provided. For example, the display driver circuitry 221 may display an image using both the first sub-pixel 321-1 and the second sub-pixel 322-1. With respect to the first point 951, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 500 nits.

Referring to the graph 950, at a second point 952, the privacy display mode among the display modes of the display 220 may be provided. For example, the display driver circuitry 221 may display an image using the second sub-pixel 322-1 among the first sub-pixel 321-1 and the second sub-pixel 322-1. With respect to the second point 952, the display driver circuitry 221 may determine (or generate) a data voltage to be applied to the second sub-pixel 322-1. For example, the display driver circuitry 221 may identify a brightness level based on a luminance value used for determining a data voltage to be applied to the second sub-pixel 322-1 as about 700 nits.

For example, the display driver circuitry 221 may gradually increase a luminance value during a time interval to gradually increase a data voltage to be applied to the second sub-pixel 322-1. For example, the time interval may be defined as a time interval between a first timing at which the event is identified by at least one processor 210 and a second timing at which a switching to the privacy display mode is completed. In the graph 950, the first timing may be substantially identical to a timing indicated by the first point 951, and the second timing may be substantially identical to a timing indicated by the second point 952. As a non-limiting example, a length of the time interval may be defined by 32 frames. For example, each of the frames may be defined by a vertical synchronization signal generated (or transmitted) by the display 220. For example, a length of the frames may correspond to a period at which the vertical synchronization signal is generated (or transmitted). The gradual increase of the luminance value is described with reference to lines 961, 962, 963, and 964 of the graph 950.

Each of the lines 961, 962, 963, and 964 may indicate a luminance value that is gradually increased from a first luminance value (e.g., about 500 nits) indicated by the first point 951 to a second luminance value (e.g., about 700 nits) indicated by the second point 952.

For example, the line 961 may be referred to as a linear curve. Referring to the line 961, the display driver circuitry 221 may uniformly increase, over time, the luminance value associated with the second sub-pixel 322-1 from the first luminance value to the second luminance value, within the time interval. As a non-limiting example, a rate of change (or an increase amount) of the luminance value according to the line 961 may be about 6 nits per frame. For example, the display driver circuitry 221 may gradually increase the luminance value within the time interval (or 32 frames), in the order of 500 nits, 506 nits, 512 nits, ... , 694 nits, and 700 nits.

For example, the line 962 may be referred to as a gamma curve. Referring to the line 962, the display driver circuitry 221 may non-uniformly increase, over time, the luminance value associated with the second sub-pixel 322-1 from the first luminance value to the second luminance value, within the time interval. For example, the display driver circuitry 221 may identify, at a third timing next to 16 frames from the first timing, the luminance value as a third luminance value increased from the first luminance value. As a non-limiting example, the third luminance value may be about 550 nits. The display driver circuitry 221 may identify, at the second timing next to 16 frames from the third timing, the luminance value as the second luminance value.

For example, the line 963 may be referred to as an inverted-gamma curve. Referring to the line 963, the display driver circuitry 221 may non-uniformly increase, over time, the luminance value associated with the second sub-pixel 322-1 from the first luminance value to the second luminance value, within the time interval. For example, the display driver circuitry 221 may identify, at a third timing next to 16 frames from the first timing, the luminance value as a third luminance value increased from the first luminance value. As a non-limiting example, the third luminance value may be about 650 nits. The display driver circuitry 221 may identify, at the second timing next to 16 frames from the third timing, the luminance value as the second luminance value. In other words, a rate of change (or an increase amount) of the luminance value according to the line 963 may be opposite to a rate of change (or an increase amount) of the luminance value according to the line 962.

For example, the line 964 may be referred to as an S curve. Referring to the line 964, the display driver circuitry 221 may non-uniformly increase, over time, the luminance value associated with the second sub-pixel 322-1 from the first luminance value to the second luminance value, within the time interval. For example, the display driver circuitry 221 may identify, at a third timing next to 8 frames from the first timing, the luminance value as a third luminance value increased from the first luminance value. As a non-limiting example, the third luminance value may be about 520 nits. For example, the display driver circuitry 221 may identify, at a fourth timing next to 8 frames from the third timing, the luminance value as a fourth luminance value increased from the third luminance value. As a non-limiting example, the fourth luminance value may be about 600 nits. For example, the display driver circuitry 221 may identify, at a fifth timing next to 8 frames from the fourth timing, the luminance value as a fifth luminance value increased from the fourth luminance value. As a non-limiting example, the fifth luminance value may be about 680 nits. In other words, according to the line 964, the luminance value may be increased by a first value within a first partial time including the first timing, and may be increased by the first value within a second partial time including the second timing and having the same length as the first partial time. The luminance value may be increased by a second value different from the first value, within a third partial time between the first partial time and the second partial time.

A rate of change (or an increase amount) of a grayscale level according to the lines 961, 962, 963, and 964 may be indicated by commands transmitted from at least one processor 210 to the display driver circuitry 221. For example, at least one processor 210 may identify a rate of change (or an increase amount) of a luminance value using an identified curve among curves stored in the memory 230. For example, at least one processor 210 may transmit, to the display driver circuitry 221, a command indicating the identified rate of change (or an increase amount) of the luminance value (or a luminance value to be changed). Specific details regarding the commands are described below with reference to FIG. 10.

Referring to the state 970, a gradual increase in a brightness level provided through the second sub-pixel 322-1 according to a gradual increase in a luminance value associated with the second sub-pixel 322-1 is illustrated. The brightness level provided through the second sub-pixel 322-1 may indicate a brightness level of the second sub-pixel 322-1 (or a portion of an image displayed through the second sub-pixel 322-1) viewable (or recognizable) from outside the display 220 (or the display panel 160, or the electronic device 101).

Referring to the example 971 of the state 970, a brightness level provided through the second sub-pixel 322-1 to which a third data voltage according to the first luminance value is applied may be a third brightness level. Referring to an example 972 of the state 970, a brightness level provided through the second sub-pixel 322-1 to which a fourth data voltage according to the second luminance value is applied may be a fourth brightness level. For example, the fourth brightness level may be higher than the third brightness level. For example, a voltage level of the fourth data voltage may be higher than a voltage level of the third data voltage. As a non-limiting example, the fourth luminance value may be a luminance value set to compensate luminance in the privacy display mode. The fourth brightness level may be referred to as another brightness level defined as a brightness level to be provided after switching to the privacy display mode is completed.

Although not illustrated in the state 970, a brightness level provided through the second sub-pixel 322-1 may gradually increase from the third brightness level to the fourth brightness level during a time interval in which the normal display mode is switched to the privacy display mode. A rate of change (or an amount of increase) at which the brightness level provided through the second sub-pixel 322-1 gradually increases may be determined according to a curve indicating a rate of change (or an amount of increase) of a gradual increase of a luminance value associated with the second sub-pixel 322-1.

Referring to FIG. 9B, the display driver circuitry 221 may gradually adjust a brightness level provided through the second sub-pixel 322-1 by gradually adjusting a luminance value to be applied to the second sub-pixel 322-1. As the brightness level provided through the second sub-pixel 322-1 is gradually adjusted, a brightness level viewable from outside the display 220 may increase within the privacy display mode of the display 220.

Referring to the lines 961, 962, 963, and 964 of the graph 950, a grayscale level of the first sub-pixel 321-1 gradually changed while a display mode of the display 220 is switched to the normal display mode, a DBV table for adjusting a luminance value associated with the second sub-pixel 322-1, luminance curves (e.g., the lines 961, 962, 963, and 964) for adjusting a brightness level of the display 220, and/or the number (e.g., 32) of frames between a timing indicated by the first point 951 and a timing indicated by the second point 952 (or a frequency defined from the timing indicated by the first point 951 and the timing indicated by the second point 952) are described, but the present disclosure is not limited thereto. For example, at least one of the grayscale level of the first sub-pixel 321-1 gradually changed, the DBV table for adjusting the luminance value associated with the second sub-pixel 322-1, the luminance curves (e.g., the lines 961, 962, 963, and 964) for adjusting the brightness level of the display 220, and/or the number (e.g., 32) of frames between the timing indicated by the first point 951 and the timing indicated by the second point 952 (or the frequency defined from the timing indicated by the first point 951 and the timing indicated by the second point 952) may be changed or determined based on a burn-in state of the second sub-pixel 322-1 (e.g., a degree to which the second sub-pixel 322-1 is burned).

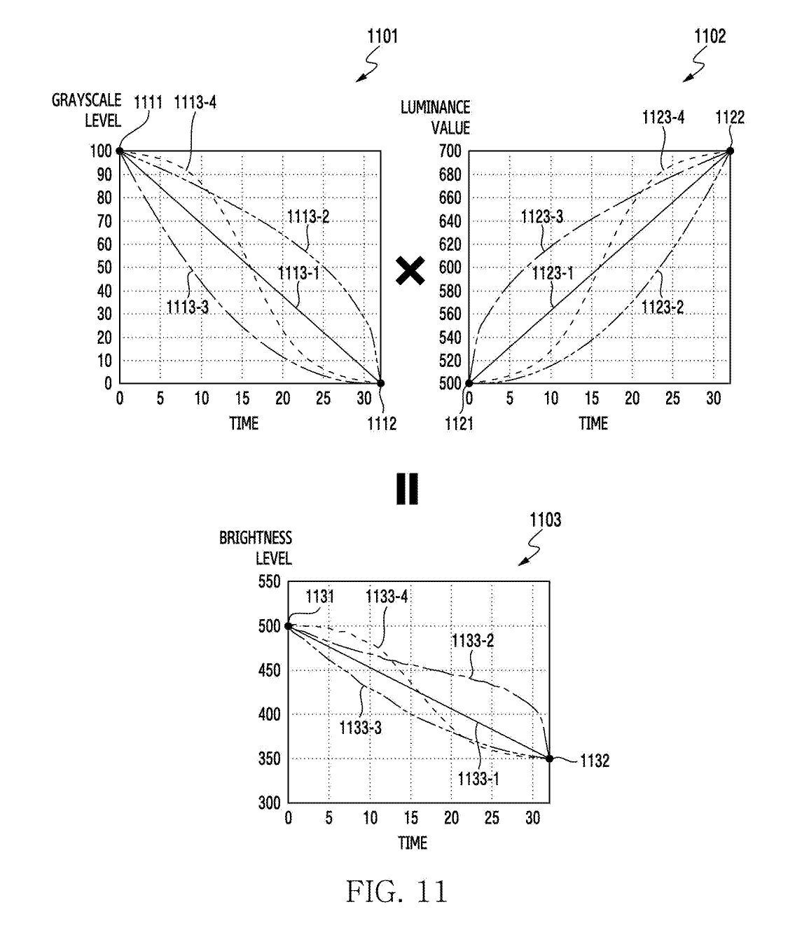

Referring to FIGS. 8 and 9B, the display driver circuitry 221 may switch the display mode of the display 220, by performing a gradual adjustment for a grayscale level to be applied to the first sub-pixel 321-1 and/or a gradual adjustment for a luminance value to be applied to the second sub-pixel 322-1. Referring to FIGS. 8 and 9B, it is described that the display driver circuitry 221 performs the gradual adjustment for the grayscale level to be applied to the first sub-pixel 321-1 and the gradual adjustment for the luminance value to be applied to the second sub-pixel 322-1 independently, but the present disclosure is not limited thereto. For example, the display driver circuitry 221 may perform the gradual adjustment for the grayscale level to be applied to the first sub-pixel 321-1 and the gradual adjustment for the luminance value to be applied to the second sub-pixel 322-1 simultaneously (or together). Details related thereto are described below with reference to FIGS. 11-13.

FIG. 10 is a diagram illustrating example commands transmitted from at least one processor to display driver circuitry, a change in time intervals during which the commands are transmitted, and a change in a period during which the commands are transmitted, while a display mode of a display is switched according to various embodiments.

Referring to FIG. 10, at least one processor 210 may transmit a command 1000 to the display driver circuitry 221 (or the display 220). In the present disclosure, the command 1000 may be referred to as a signal, a request, a command signal, or a control signal. As a non-limiting example, the command 1000 may be transmitted through an interface connecting at least one processor 210 and the display driver circuitry 221. For example, the interface may be referred to as a mobile industry processor interface (MIPI) (or a MIPI display serial interface (DSI)).

For example, the command may be used for a gradual adjustment of a grayscale level associated with the first sub-pixel 321-1. The command used for the gradual adjustment of the grayscale level associated with the first sub-pixel 321-1 may be referred to as a wide pixel control (WPC) command. For example, the command may be used for a gradual adjustment of a luminance value associated with the second sub-pixel 322-1. The command used for the gradual adjustment of the luminance value associated with the second sub-pixel 322-1 may be referred to as a DBV command. As a non-limiting example, the command may include the WPC command and/or the DBV command.

For example, at least one processor 210 may periodically transmit the command while performing the switching of the display mode of the display 220. In other words, at least one processor 210 may transmit, to the display driver circuitry 221, commands (or a command sequence) while performing the switching of the display mode of the display 220 to perform a gradual adjustment of a grayscale level and/or a gradual adjustment of a luminance value. The commands transmitted from at least one processor 210 to the display driver circuitry 221 are described with reference to examples 1010, 1020, and 1030.

Referring to example 1010, the commands may be transmitted from at least one processor 210 to the display driver circuitry 221 within a time interval 1019 between a first timing 1001 and a second timing 1002. As a non-limiting example, the first timing 1001 may be a timing at which the event is identified by at least one processor 210. As a non-limiting example, the second timing 1002 may be a timing at which the switching to the privacy display mode is completed (or the privacy display mode is provided). For example, at least one processor 210 may transmit a command to the display driver circuitry 221 at the first timing 1001. For example, at least one processor 210 may transmit a command to the display driver circuitry 221 within the time interval 1019, according to a period 1017. The period 1017 may be defined from the first timing 1001. As a non-limiting example, at least one processor 210 may transmit eight commands according to the period 1017 within the time interval 1019. The eight commands are merely examples for convenience of explanation, and the present disclosure is not limited thereto. For example, the number of commands transmitted from at least one processor 210 to the display driver circuitry 221 may be greater than eight or less than seven. For example, the period 1017 may be referred to as a frequency, a refresh rate, or a driving frequency. For example, when a refresh rate defined in the electronic device 101 (or the display 220, the display driver circuitry 221, or at least one processor 210) is 60 Hz, commands transmitted from at least one processor 210 to the display driver circuitry 221 may be sixty within a unit time (e.g., 1 second).

A length of the period 1017 and/or a length of the time interval 1019 illustrated in the example 1010 may be adjusted. For example, at least one processor 210 may decrease or increase the length of the time interval 1019. For example, at least one processor 210 may decrease or increase the length of the period 1017.

For example, at least one processor 210 may adjust (or set) the number of frames included in the time interval 1019, based on at least one of a characteristic (or optical characteristic) of light-emitting elements (or sub-pixels) of the display 220 (or the display panel 160), a characteristic (or optical characteristic) according to luminance of the display 220 (or the display panel 160), a curve for WPC, or a curve for DBV. As a non-limiting example, at least one processor 210 may set the number of the frames included in the time section 1019 to thirty-two. For example, at least one processor 210 may adjust (or set) the length of the period 1017 based on at least one of a characteristic (or optical characteristic) of light-emitting elements (or sub-pixels) of the display 220 (or the display panel 160), a characteristic (or optical characteristic) according to luminance of the display 220 (or the display panel 160), a curve for WPC, or a curve for DBV. As a non-limiting example, at least one processor 210 may set the length of the period 1017 to a length (e.g., 8.333 milliseconds (ms)) according to 120 Hz.

For example, at least one processor 210 may define a curve for WPC, a curve for DBV, a length of a set time interval, and a length of a set period as one data set, and may store the defined data set in the memory 230. For example, at least one processor 210 may store a plurality of defined data sets in the memory 230. For example, at least one processor 210 may identify an event for switching the display mode of the display 220, and may generate a command 1000 according to a data set based on the identified event. For example, at least one processor 210 may transmit the generated command 1000 to the display driver circuitry 221.

A length of a time interval adjusted from a length of the time interval 1019 of the example 1010 is described with reference to the example 1020. A length of a period adjusted from a length of the period 1017 of the example 1010 is described with reference to the example 1030.

Referring to the example 1020, the commands may be transmitted from at least one processor 210 to the display driver circuitry 221 within a time interval 1029 between the first timing 1001 and the second timing 1002. For example, a length of the time interval 1029 may be longer than a length of the time interval 1019. However, the present disclosure is not limited thereto. For example, the length of the time interval 1029 may be shorter than the length of the time interval 1019. For example, at least one processor 210 may transmit a command to the display driver circuitry 221 at the first timing 1001. For example, at least one processor 210 may transmit a command to the display driver circuitry 221 within the time interval 1029, according to the period 1017. As a non-limiting example, at least one processor 210 may transmit ten commands within the time interval 1029, according to the period 1017. The ten commands are merely examples for convenience of explanation, and the present disclosure is not limited thereto. Since a length of the time interval 1029 in which the commands illustrated in the example 1020 are transmitted is longer than a length of the time interval 1019 in which the commands illustrated in the example 1010 are transmitted, a time for switching the display mode of the display 220 in the example 1020 may be longer than a time for switching the display mode of the display 220 in the example 1010. As a time for switching the display mode of the display 220 becomes longer, a change in a brightness level of the display 220 may be recognized more slowly by a user.

Referring to the example 1030, the commands may be transmitted from at least one processor 210 to the display driver circuitry 221, within a time interval 1019 between the first timing 1001 and the second timing 1002. For example, a length of a period 1037 may be shorter than a length of a period 1017. However, the present disclosure is not limited thereto. For example, a length of the period 1037 may be longer than a length of the period 1017. For example, at least one processor 210 may transmit a command to the display driver circuitry 221 at the first timing 1001. For example, at least one processor 210 may transmit a command to the display driver circuitry 221 within the time interval 1019, according to the period 1037. As a non-limiting example, at least one processor 210 may transmit more than ten commands within the time interval 1019, according to the period 1037. Since a length of the period 1037 in which the commands illustrated in the example 1030 are transmitted is shorter than a length of the period 1017 in which the commands illustrated in the example 1010 are transmitted, a change in a brightness level of the display 220 while the display mode of the display 220 is switched in the example 1030 may be caused more frequently than a change in a brightness level of the display 220 while the display mode of the display 220 is switched in the example 1010. As a length of the period 1037 becomes shorter, a change in a brightness level of the display 220 may be recognized more quickly by a user.

As a non-limiting example, at least one processor 210 may adjust a length of a time interval (e.g., the time interval 1019 or the time interval 1029) and/or a length of a period (e.g., the period 1017 or the period 1037), based on an illuminance value. For example, at least one processor 210 may adjust the length of the period to a length of a period according to 120 Hz and may relatively increase the length of the time interval (or the number of frames included in the time interval), based on identifying an illuminance value less than a reference illuminance value (or low illuminance). This may be to relatively slowly perform the switching of the display mode of the display 220 because a user is relatively sensitive to a luminance change in an environment having a relatively low illuminance value. At least one processor 210 may adjust the length of the period to a length of a period according to 30 Hz (or 24 Hz) and may relatively decrease the length of the time interval (or the number of frames included in the time interval), based on identifying an illuminance value exceeding (or equal to or greater than) the reference illuminance value (or high illuminance). This may be to relatively quickly perform the switching of the display mode of the display 220 because a user is relatively insensitive to a luminance change in an environment having a relatively high illuminance value. As the switching of the display mode becomes faster, power consumption of the electronic device 101 may be reduced.

Although examples 1010, 1020, and 1030 of FIG. 10 describe examples in which a plurality of commands are transmitted within a time interval (e.g., the time interval 1019 or the time interval 1029), the present disclosure is not limited thereto. For example, at least one processor 210 may cause to perform a gradual change in a brightness level of the display 220 within the time interval (e.g., the time interval 1019 or the time interval 1029), by transmitting one command to the display driver circuitry 221 at the first timing 1001. For example, the one command may include a length of the time interval, a period at which a grayscale level and/or a luminance value are to be changed, and a change rate of a grayscale level and/or a change rate of a luminance value (or information regarding a slope of a curve).

FIG. 11 includes graphs illustrating an example of gradually changing a grayscale level associated with a first sub-pixel, gradually changing a luminance value associated with a second sub-pixel, and gradually changing a brightness level of a display, while a display mode of the display is switched from a normal display mode to a privacy display mode according to various embodiments.

Referring to FIG. 11, a graph 1101 indicating a gradual decrease of a grayscale level associated with the first sub-pixel 321-1, a graph 1102 indicating a gradual increase of a luminance value associated with the second sub-pixel 322-1, and a graph 1103 indicating a gradual decrease of a brightness level of the display 220 while the display mode of the display 220 is switched from the normal display mode to the privacy display mode are illustrated.

A horizontal axis of the graph 1101 indicates time (unit: frame), and a vertical axis of the graph 1101 indicates a ratio of a grayscale level with respect to a grayscale value (unit: percent (%)). A horizontal axis of the graph 1102 indicates time (unit: frame), and a vertical axis of the graph 1102 indicates a luminance value (unit: nit). A horizontal axis of the graph 1103 indicates time (unit: frame), and a vertical axis of the graph 1103 indicates a brightness level (unit: nit). In the graph 1103, frames changed while a brightness level is changed may be referred to as transition frames.

Referring to the graph 1101, at a first point 1111, the normal display mode among the display modes of the display 220 may be provided. For example, the display driver circuitry 221 may display an image using both the first sub-pixel 321-1 and the second sub-pixel 322-1. In FIG. 11, for convenience of explanation, a grayscale value of a portion of an image received from at least one processor 210 corresponding to the first sub-pixel 321-1 may be 255G. For example, the display driver circuitry 221 may identify a grayscale level used for determining a data voltage to be applied to the first sub-pixel 321-1 as 255G, according to a ratio of 100%. Accordingly, at a timing (e.g., a first frame) indicated by the first point 1111, a brightness level provided through the first sub-pixel 321-1 may be a first brightness level (e.g., about 500 nits).

Referring to the graph 1102, at a first point 1121, the normal display mode among the display modes of the display 220 may be provided. A time indicated by the first point 1121 may be identical to a time indicated by the first point 1111. For example, the display driver circuitry 221 may display an image using both the first sub-pixel 321-1 and the second sub-pixel 322-1. At the first point 1121, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 500 nits. Accordingly, at a timing (e.g., a first frame) indicated by the first point 1121, a brightness level provided through the second sub-pixel 322-1 may be a third brightness level (e.g., about 500 nits).

Referring to the graph 1103, at a first point 1131, the normal display mode among the display modes of the display 220 may be provided. A time indicated by the first point 1131 may be identical to a time indicated by the first point 1111 (and the first point 1121). For example, the display driver circuitry 221 may display an image using both the first sub-pixel 321-1 and the second sub-pixel 322-1. At the first point 1131, a brightness level of the display 220 may be determined by the first brightness level and the third brightness level. As a non-limiting example, at the first point 1131, the brightness level of the display 220 may be a fifth brightness level (e.g., about 500 nits).

Referring back to the graph 1101, at a second point 1112, the privacy display mode among the display modes of the display 220 may be provided. For example, the display driver circuitry 221 may display an image using the second sub-pixel 322-1 among the first sub-pixel 321-1 and the second sub-pixel 322-1. For example, the display driver circuitry 221 may identify a grayscale level used for determining a data voltage to be applied to the first sub-pixel 321-1 as 0G, according to a ratio of 0%. Accordingly, at a timing indicated by the first point 1111 (e.g., a thirty-second frame), a brightness level provided through the first sub-pixel 321-1 may be a second brightness level (e.g., about 0 nits). For example, the second brightness level may be lower than the first brightness level. As a non-limiting example, the second brightness level may be a brightness level indicating a black color.

Referring to the graph 1102, at a second point 1122, the privacy display mode among the display modes of the display 220 may be provided. A time indicated by the second point 1122 may be identical to a time indicated by the second point 1112. For example, the display driver circuitry 221 may display an image using the second sub-pixel 322-1 among the first sub-pixel 321-1 and the second sub-pixel 322-1. At the second point 1122, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 700 nits. Accordingly, at a timing indicated by the second point 1122 (e.g., a thirty-second frame), a brightness level provided through the second sub-pixel 322-1 may be a fourth brightness level (e.g., about 700 nits). For example, the fourth brightness level may be higher than the third brightness level.

Referring to the graph 1103, at a second point 1132, the privacy display mode among the display modes of the display 220 may be provided. A time indicated by the second point 1132 may be identical to a time indicated by the second point 1112 (and the second point 1122). For example, the display driver circuitry 221 may display an image using the second sub-pixel 322-1 among the first sub-pixel 321-1 and the second sub-pixel 322-1. At the second point 1132, a brightness level of the display 220 may be determined by the second brightness level and the fourth brightness level. As a non-limiting example, at the second point 1132, a brightness level of the display 220 may be a sixth brightness level (e.g., about 350 nits).

The display driver circuitry 221 may perform switching of the display mode of the display 220 from the normal display mode to the privacy display mode, based on at least one command received from at least one processor 210. For example, the display driver circuitry 221 may gradually decrease the brightness level of the display 220, by gradually decreasing a grayscale level and gradually increasing a luminance value within a time interval between a timing (e.g., a first frame) indicated by the first point 1111 (or the first point 1121 or the first point 1131) and a timing (e.g., a thirty-second frame) indicated by the second point 1112 (or the second point 1122 or the second point 1132).

As illustrated through lines 1113-1, 1113-2, 1113-3, and 1113-4 of the graph 1101, the display driver circuitry 221 may gradually decrease a grayscale level associated with the first sub-pixel 321-1 within the time interval. Specific details regarding the lines 1113-1, 1113-2, 1113-3, and 1113-4 may be substantially the same as those described for the lines 811, 812, 813, and 814 of the graph 800 of FIG. 8.

As illustrated through lines 1123-1, 1123-2, 1123-3, and 1123-4 of the graph 1102, the display driver circuitry 221 may gradually increase a luminance value associated with the second sub-pixel 322-1 within the time interval. Details regarding the lines 1123-1, 1123-2, 1123-3, and 1123-4 may be substantially the same as those described for the lines 961, 962, 963, and 964 of the graph 950 of FIG. 9B.

As illustrated through lines 1133-1, 1133-2, 1133-3, and 1133-4 of the graph 1103, a brightness level of the display 220 may be gradually decreased from the fifth brightness level to the sixth brightness level. For example, the line 1133-1 may be referred to as a linear curve. A gradual decrease in the brightness level of the display 220 according to the line 1133-1 may be caused by a gradual decrease in the grayscale level according to the line 1113-1 and a gradual increase in the luminance value according to the line 1123-1. For example, the line 1133-2 may be referred to as an inverted-gamma curve. A gradual decrease in the brightness level of the display 220 according to the line 1133-2 may be caused by a gradual decrease in the grayscale level according to the line 1113-2 and a gradual increase in the luminance value according to the line 1123-2. For example, the line 1133-3 may be referred to as a gamma curve. A gradual decrease in the brightness level of the display 220 according to the line 1133-3 may be caused by a gradual decrease in the grayscale level according to the line 1113-3 and a gradual increase in the luminance value according to the line 1123-3. For example, the line 1133-4 may be referred to as an S curve. A gradual decrease in the brightness level of the display 220 according to the line 1133-4 may be caused by a gradual decrease in the grayscale level according to the line 1113-4 and a gradual increase in the luminance value according to the line 1123-4.

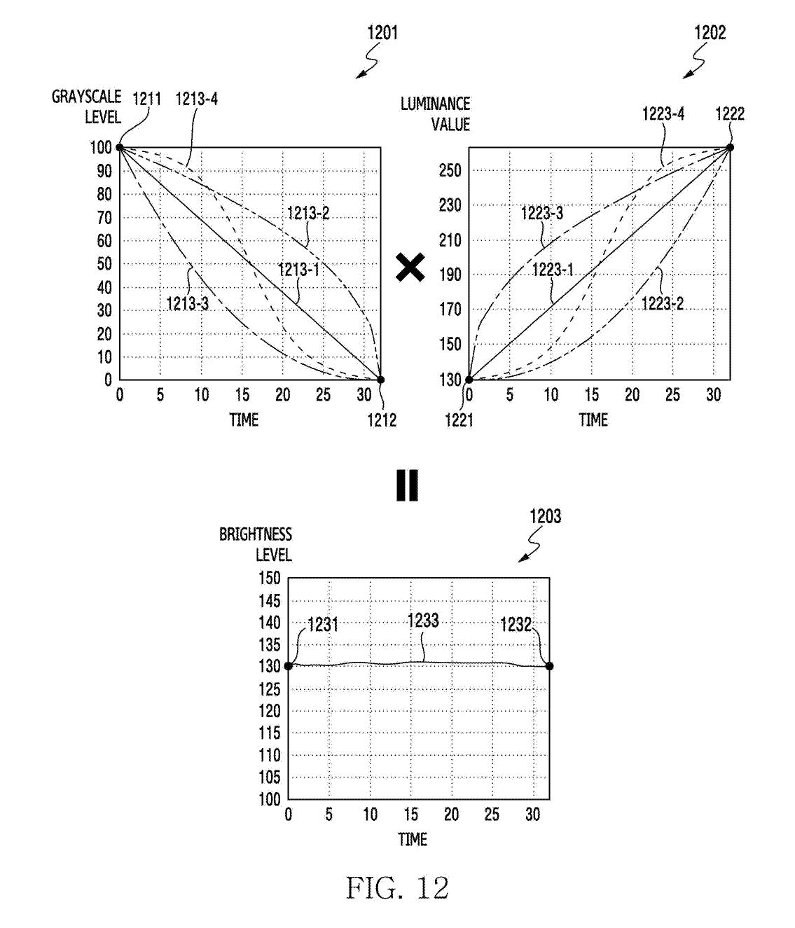

Referring to FIG. 11, although an example in which a brightness level of the display 220 is decreased from a relatively high brightness level (e.g., the fifth brightness level) to a relatively low brightness level (e.g., the sixth brightness level) when switching the display mode of the display 220 from the normal display mode to the privacy display mode is illustrated, the present disclosure is not limited thereto. For example, the electronic device 101 may substantially maintain the brightness level of the display 220 when switching the display mode of the display 220 from the normal display mode to the privacy display mode. Details related thereto are described in greater detail below with reference to FIG. 12.

FIG. 12 includes graphs illustrating an example of gradually changing a grayscale level associated with a first sub-pixel, gradually changing a luminance value associated with a second sub-pixel, and gradually changing a brightness level of a display, while a display mode of the display is switched from a normal display mode to a privacy display mode according to various embodiments.

Referring to FIG. 12, a graph 1201 indicating a gradual decrease of a grayscale level associated with the first sub-pixel 321-1, a graph 1202 indicating a gradual increase of a luminance value associated with the second sub-pixel 322-1, and a graph 1203 indicating maintenance of a brightness level of the display 220 while the display mode of the display 220 is switched from the normal display mode to the privacy display mode are illustrated.

A horizontal axis of the graph 1201 indicates time (unit: frame), and a vertical axis of the graph 1201 indicates a ratio of a grayscale level with respect to a grayscale value (unit: percent (%)). A horizontal axis of the graph 1202 indicates time (unit: frame), and a vertical axis of the graph 1202 indicates a luminance value (unit: nit). A horizontal axis of the graph 1203 indicates time (unit: frame), and a vertical axis of the graph 1203 indicates a brightness level (unit: nit).

Referring to the graph 1201, at a first point 1211, the normal display mode among the display modes of the display 220 may be provided. For example, the display driver circuitry 221 may display an image using both the first sub-pixel 321-1 and the second sub-pixel 322-1. In FIG. 12, for convenience of explanation, a grayscale value corresponding to a portion of an image received from at least one processor 210 corresponding to the first sub-pixel 321-1 may be 255G. For example, the display driver circuitry 221 may identify a grayscale level used for determining a data voltage to be applied to the first sub-pixel 321-1 as 255G, according to a ratio of 100%. Accordingly, at a timing indicated by the first point 1211 (e.g., a first frame), a brightness level provided through the first sub-pixel 321-1 may be a first brightness level (e.g., about 130 nits).

Referring to the graph 1202, at a first point 1221, the normal display mode among the display modes of the display 220 may be provided. A time indicated by the first point 1221 may be identical to a time indicated by the first point 1211. For example, the display driver circuitry 221 may display an image using both the first sub-pixel 321-1 and the second sub-pixel 322-1. At the first point 1221, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 130 nits. Accordingly, at a timing indicated by the first point 1221 (e.g., a first frame), a brightness level provided through the second sub-pixel 322-1 may be a third brightness level (e.g., about 130 nits).

Referring to the graph 1203, at a first point 1231, the normal display mode among the display modes of the display 220 may be provided. A time indicated by the first point 1231 may be identical to a time indicated by the first point 1211 (and the first point 1221). For example, the display driver circuitry 221 may display an image using both the first sub-pixel 321-1 and the second sub-pixel 322-1. At the first point 1231, a brightness level of the display 220 may be determined by the first brightness level and the third brightness level. As a non-limiting example, at the first point 1231, the brightness level of the display 220 may be a fifth brightness level (e.g., about 130 nits).

Referring back to the graph 1201, at a second point 1212, the privacy display mode among the display modes of the display 220 may be provided. For example, the display driver circuitry 221 may display an image using the second sub-pixel 322-1 among the first sub-pixel 321-1 and the second sub-pixel 322-1. For example, the display driver circuitry 221 may identify a grayscale level used for determining a data voltage to be applied to the first sub-pixel 321-1 as 0G, according to a ratio of 0%. Accordingly, at a timing indicated by the first point 1211 (e.g., a thirty-second frame), a brightness level provided through the first sub-pixel 321-1 may be a second brightness level (e.g., about 0 nits). For example, the second brightness level may be lower than the first brightness level. As a non-limiting example, the second brightness level may be a brightness level indicating a black color.

Referring to the graph 1202, at a second point 1222, the privacy display mode among the display modes of the display 220 may be provided. A time indicated by the second point 1222 may be identical to a time indicated by the second point 1212. For example, the display driver circuitry 221 may display an image using the second sub-pixel 322-1 among the first sub-pixel 321-1 and the second sub-pixel 322-1. At the second point 1222, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 260 nits. Accordingly, at a timing indicated by the second point 1222 (e.g., a thirty-second frame), a brightness level provided through the second sub-pixel 322-1 may be a fourth brightness level (e.g., about 260 nits). For example, the fourth brightness level may be higher than the third brightness level.

Referring to the graph 1203, at a second point 1232, the privacy display mode among the display modes of the display 220 may be provided. A time indicated by the second point 1232 may be identical to a time indicated by the second point 1212 (and the second point 1222). For example, the display driver circuitry 221 may display an image using the second sub-pixel 322-1 among the first sub-pixel 321-1 and the second sub-pixel 322-1. At the second point 1232, a brightness level of the display 220 may be determined by the second brightness level and the fourth brightness level. As a non-limiting example, at the second point 1232, the brightness level of the display 220 may be the fifth brightness level (e.g., about 130 nits).

The display driver circuitry 221 may perform switching of the display mode of the display 220 from the normal display mode to the privacy display mode, based on at least one command received from at least one processor 210. For example, the display driver circuitry 221 may substantially maintain a brightness level of the display 220, by gradually decreasing a grayscale level and gradually increasing a luminance value within a time interval between a timing (e.g., a first frame) indicated by the first point 1211 (or the first point 1221 or the first point 1231) and a timing (e.g., a thirty-second frame) indicated by the second point 1212 (or the second point 1222 or the second point 1232).

In the example of FIG. 12, a brightness level provided through the first sub-pixel 321-1 and a brightness level provided through the second sub-pixel 322-1 may be relatively lower than a brightness level provided through the first sub-pixel 321-1 and a brightness level provided through the second sub-pixel 322-1, described in the example of FIG. 11. However, a rate of change (or an increase amount) of the brightness level provided through the second sub-pixel 322-1 described in the example of FIG. 12 may be higher than a rate of change (or an increase amount) of the brightness level provided through the second sub-pixel 322-1 described in the example of FIG. 11. In other words, in the example of FIG. 12, the display driver circuitry 221 may set the rate of change of the brightness level provided through the second sub-pixel 322-1 higher to substantially maintain the brightness level of the display 220, when switching the display mode of the display 220 from the normal display mode to the privacy display mode.

As illustrated through lines 1213-1, 1213-2, 1213-3, and 1213-4 of the graph 1201, the display driver circuitry 221 may gradually decrease a grayscale level associated with the first sub-pixel 321-1, within the time interval. Details regarding the lines 1213-1, 1213-2, 1213-3, and 1213-4 may be substantially the same as those described for the lines 811, 812, 813, and 814 of the graph 800 of FIG. 8.

As illustrated through lines 1223-1, 1223-2, 1223-3, and 1223-4 of the graph 1202, the display driver circuitry 221 may gradually increase a luminance value associated with the second sub-pixel 322-1, within the time interval. Details regarding the lines 1223-1, 1223-2, 1223-3, and 1223-4 may be substantially the same as those described for the lines 961, 962, 963, and 964 of the graph 950 of FIG. 9B.

As illustrated through the line 1233 of the graph 1203, the brightness level of the display 220 may be substantially maintained at the fifth brightness level. For example, the line 1233 may indicate a change in the brightness level corresponding to each of a linear curve, a gamma curve, an inverted-gamma curve, or an S curve. For example, maintenance of the brightness level of the display 220 according to the line 1233 may be caused by a gradual decrease in the grayscale level according to the lines 1213-1, 1213-2, 1213-3, and 1213-4 and a gradual increase in the luminance value according to the lines 1223-1, 1223-2, 1223-3, and 1223-4.

As a non-limiting example, when an illuminance value of an external environment of the electronic device 101 is less than a reference illuminance value, the electronic device 101 may substantially maintain a brightness level of the display 220 even though a display mode of the display 220 is switched from the normal display mode to the privacy display mode. When the illuminance value is less than the reference illuminance value, a user may more sensitively recognize a change in the brightness level of the display 220. In order to improve user usability, at least one processor 210 (and/or the display 220, or the display driver circuitry 221) may substantially maintain the brightness level of the display 220 even though switching of the display mode is performed. For example, the reference illuminance value may be a value set with respect to the electronic device 101. However, the present disclosure is not limited thereto. For example, the reference illuminance value may be adjusted.

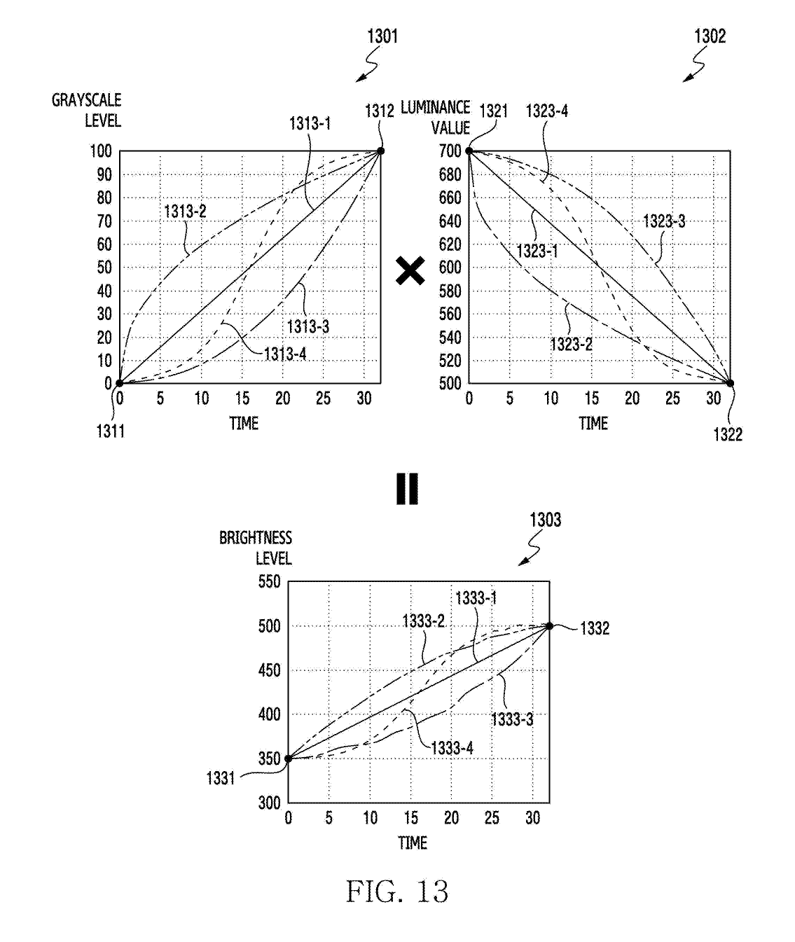

In FIGS. 11 and 12, examples in which the display mode of the display 220 is switched from the normal display mode to the privacy display mode are described, but the present disclosure is not limited thereto. Details regarding switching of the display mode of the display 220 from the privacy display mode to the normal display mode are described in greater detail below with reference to FIG. 13.

FIG. 13 includes graphs illustrating an example of gradually changing a grayscale level associated with a first sub-pixel, gradually changing a luminance value associated with a second sub-pixel, and gradually changing a brightness level of a display, while a display mode of the display is switched from a privacy display mode to a normal display mode according to various embodiments.

Referring to FIG. 13, a graph 1301 indicating a gradual increase of a grayscale level associated with the first sub-pixel 321-1, a graph 1302 indicating a gradual decrease of a luminance value associated with the second sub-pixel 322-1, and a graph 1303 indicating a gradual increase of a brightness level of the display 220 while the display mode of the display 220 is switched from the privacy display mode to the normal display mode are illustrated.

A horizontal axis of the graph 1301 indicates time (unit: frame), and a vertical axis of the graph 1301 indicates a ratio of a grayscale level to a grayscale value (unit: percent (%)). A horizontal axis of the graph 1302 indicates time (unit: frame), and a vertical axis of the graph 1302 indicates a luminance value (unit: nit). A horizontal axis of the graph 1303 indicates time (unit: frame), and a vertical axis of the graph 1303 indicates a brightness level (unit: nit). In the graph 1303, frames in which the brightness level is changed while the brightness level is changed may be referred to as transition frames.

Referring to the graph 1301, at a first point 1311, the privacy display mode among the display modes of the display 220 may be provided. For example, the display driver circuitry 221 may display an image using the second sub-pixel 322-1 among the first sub-pixel 321-1 and the second sub-pixel 322-1. In FIG. 13, for convenience of explanation, a grayscale value corresponding to a portion of an image received from at least one processor 210 corresponding to the first sub-pixel 321-1 may be 255G. For example, the display driver circuitry 221 may identify a grayscale level used for determining a data voltage to be applied to the first sub-pixel 321-1 as 0G, according to a ratio of 0%. Accordingly, at a timing indicated by the first point 1311 (e.g., a first frame), a brightness level provided through the first sub-pixel 321-1 may be a second brightness level (e.g., about 0 nits). As a non-limiting example, the second brightness level may be a brightness level indicating a black color.

Referring to the graph 1302, at a first point 1321, the privacy display mode among the display modes of the display 220 may be provided. A time indicated by the first point 1321 may be identical to a time indicated by the first point 1311. For example, the display driver circuitry 221 may display an image using the second sub-pixel 322-1 among the first sub-pixel 321-1 and the second sub-pixel 322-1. At the first point 1321, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 700 nits. Accordingly, at a timing indicated by the first point 1321 (e.g., a first frame), a brightness level provided through the second sub-pixel 322-1 may be a fourth brightness level (e.g., about 700 nits).

Referring to the graph 1303, at a first point 1331, the privacy display mode among the display modes of the display 220 may be provided. A time indicated by the first point 1331 may be identical to a time indicated by the first point 1311 (and the first point 1321). For example, the display driver circuitry 221 may display an image using the second sub-pixel 322-1 among the first sub-pixel 321-1 and the second sub-pixel 322-1. At the first point 1331, a brightness level of the display 220 may be determined by the second brightness level and the fourth brightness level. As a non-limiting example, at the first point 1331, the brightness level of the display 220 may be a sixth brightness level (e.g., about 350 nits).

Referring back to the graph 1301, at a second point 1312, the normal display mode among the display modes of the display 220 may be provided. For example, the display driver circuitry 221 may display an image using both the first sub-pixel 321-1 and the second sub-pixel 322-1. For example, the display driver circuitry 221 may identify a grayscale level used for determining a data voltage to be applied to the first sub-pixel 321-1 as 255G, according to a ratio of 100%. Accordingly, at a timing indicated by the first point 1311 (e.g., a thirty-second frame), a brightness level provided through the first sub-pixel 321-1 may be a first brightness level (e.g., about 500 nits). For example, the first brightness level may be higher than the second brightness level.

Referring to the graph 1302, at a second point 1322, the normal display mode among the display modes of the display 220 may be provided. A time indicated by the second point 1322 may be identical to a time indicated by the second point 1312. For example, the display driver circuitry 221 may display an image using both the first sub-pixel 321-1 and the second sub-pixel 322-1. At the second point 1322, the display driver circuitry 221 may determine (or generate) a data voltage to be applied to the second sub-pixel 322-1. For example, the display driver circuitry 221 may identify a luminance value used for determining a data voltage to be applied to the second sub-pixel 322-1 as about 500 nits. Accordingly, at a timing indicated by the second point 1322 (e.g., a thirty-second frame), a brightness level provided through the second sub-pixel 322-1 may be a third brightness level (e.g., about 500 nits). For example, the third brightness level may be lower than the fourth brightness level.

Referring to the graph 1303, at a second point 1332, the normal display mode among the display modes of the display 220 may be provided. A time indicated by the second point 1332 may be identical to a time indicated by the second point 1312 (and the second point 1322). For example, the display driver circuitry 221 may display an image using both the first sub-pixel 321-1 and the second sub-pixel 322-1. At the second point 1332, a brightness level of the display 220 may be determined by the first brightness level and the third brightness level. As a non-limiting example, at the second point 1332, the brightness level of the display 220 may be a fifth brightness level (e.g., about 500 nits).

The display driver circuitry 221 may perform switching of the display mode of the display 220 from the privacy display mode to the normal display mode, based on at least one command received from at least one processor 210. For example, the display driver circuitry 221 may gradually increase a brightness level of the display 220, by gradually increasing a grayscale level and gradually decreasing a luminance value within a time interval between a timing (e.g., a first frame) indicated by the first point 1311 (or the first point 1321 or the first point 1331) and a timing (e.g., a thirty-second frame) indicated by the second point 1312 (or the second point 1322 or the second point 1332).

As illustrated through lines 1313-1, 1313-2, 1313-3, and 1313-4 of the graph 1301, the display driver circuitry 221 may gradually increase a grayscale level associated with the first sub-pixel 321-1 within the time interval. As illustrated through lines 1323-1, 1323-2, 1323-3, and 1323-4 of the graph 1302, the display driver circuitry 221 may gradually decrease a luminance value associated with the second sub-pixel 322-1 within the time interval.

As illustrated through lines 1333-1, 1333-2, 1333-3, and 1333-4 of the graph 1303, a brightness level of the display 220 may be gradually increased from the sixth brightness level to the fifth brightness level. For example, the line 1333-1 may be referred to as a linear curve. A gradual increase in the brightness level of the display 220 according to the line 1333-1 may be caused by a gradual increase in the grayscale level according to the line 1313-1 and a gradual decrease in the luminance value according to the line 1323-1. For example, the line 1333-2 may be referred to as an inverted-gamma curve. A gradual increase in the brightness level of the display 220 according to the line 1333-2 may be caused by a gradual increase in the grayscale level according to the line 1313-2 and a gradual decrease in the luminance value according to the line 1323-2. For example, the line 1333-3 may be referred to as a gamma curve. A gradual increase in the brightness level of the display 220 according to the line 1333-3 may be caused by a gradual increase in the grayscale level according to the line 1313-3 and a gradual decrease in the luminance value according to the line 1323-3. For example, the line 1333-4 may be referred to as an S curve. A gradual increase in the brightness level of the display 220 according to the line 1333-4 may be caused by a gradual increase in the grayscale level according to the line 1313-4 and a gradual decrease in the luminance value according to the line 1323-4.

In FIGS. 8-13, it is described that a gradual adjustment of a grayscale level and/or a gradual adjustment of a luminance value is performed in all sub-pixels of the display panel 160 when switching of the display mode of the display 220, but the present disclosure is not limited thereto. For example, the display driver circuitry 221 may independently drive the display modes with respect to a portion of a display area of the display panel 160 and another portion distinguished from the portion of the display area. As a non-limiting example, the display driver circuitry 221 may be driven at the other portion in the normal display mode and may be driven at the portion in the privacy display mode. As described above, the privacy display mode partially driven at the display area of the display panel 160 may be referred to as a partial privacy display mode. For example, the first sub-pixel 321-1 and the second sub-pixel 322-2 may be arranged at the portion of the display area, and the third sub-pixel and the fourth sub-pixel may be arranged at the other portion. For example, the third sub-pixel may be used for the normal display mode among the normal display mode and the privacy display mode. For example, the fourth sub-pixel may be used for both the normal display mode and the privacy display mode.

As a non-limiting example, the display driver circuitry 221 may perform a gradual change of a grayscale level associated with a sub-pixel (e.g., the first sub-pixel 321-1) of the portion of a display area in which the partial privacy display mode is provided, to provide the partial privacy display mode according to switching of the display mode of the display 220. In addition, the display driver circuitry 221 may adjust a length of a time interval (e.g., the time interval 1019 of FIG. 10) and/or a length of a period (e.g., the period 1017 of FIG. 10) in which the switching is performed, to provide the partial privacy display mode according to switching of the display mode of the display 220.

Referring to FIGS. 1-13, the electronic device 101 according to the present disclosure may perform a smooth switching of the display mode of the display 220. For example, the electronic device 101 may perform a smooth switching of the display mode of the display 220, based on a gradual change of a grayscale level, a gradual change of a luminance value, use (or adjustment) of a time interval for switching the display mode, and use (or adjustment) of a period for transmitting a command for the gradual change of the grayscale level and/or the gradual change of the luminance value. Accordingly, the electronic device 101 according to the present disclosure may improve user usability by reducing a possibility that the switching of the display mode for adjusting visibility is recognized by a user.

The effects that can be obtained from the present disclosure are not limited to those described above, and any other effects not mentioned herein will be clearly understood by those having ordinary knowledge in the art to which the present disclosure belongs.

FIG. 14 is a block diagram illustrating an example electronic device 1401 in a network environment 1400 according to various embodiments.

Referring to FIG. 14, the electronic device 1401 in the network environment 1400 may communicate with an electronic device 1402 via a first network 1498 (e.g., a short-range wireless communication network), or at least one of an electronic device 1404 or a server 1408 via a second network 1499 (e.g., a long-range wireless communication network). According to an embodiment, the electronic device 1401 may communicate with the electronic device 1404 via the server 1408. According to an embodiment, the electronic device 1401 may include a processor 1420, memory 1430, an input module 1450, a sound output module 1455, a display module 1460, an audio module 1470, a sensor module 1476, an interface 1477, a connecting terminal 1478, a haptic module 1479, a camera module 1480, a power management module 1488, a battery 1489, a communication module 1490, a subscriber identification module (SIM) 1496, or an antenna module 1497. In various embodiments, at least one of the components (e.g., the connecting terminal 1478) may be omitted from the electronic device 1401, or one or more other components may be added in the electronic device 1401. In various embodiments, some of the components (e.g., the sensor module 1476, the camera module 1480, or the antenna module 1497) may be implemented as a single component (e.g., the display module 1460).

The processor 1420 may execute, for example, software (e.g., a program 1440) to control at least one other component (e.g., a hardware or software component) of the electronic device 1401 coupled with the processor 1420, and may perform various data processing or computation. According to an embodiment, as at least part of the data processing or computation, the processor 1420 may store a command or data received from another component (e.g., the sensor module 1476 or the communication module 1490) in volatile memory 1432, process the command or the data stored in the volatile memory 1432, and store resulting data in non-volatile memory 1434. According to an embodiment, the processor 1420 may include a main processor 1421 (e.g., a central processing unit (CPU) or an application processor (AP)), or an auxiliary processor 1423 (e.g., a graphics processing unit (GPU), a neural processing unit (NPU), an image signal processor (ISP), a sensor hub processor, or a communication processor (CP)) that is operable independently from, or in conjunction with, the main processor 1421. For example, when the electronic device 1401 includes the main processor 1421 and the auxiliary processor 1423, the auxiliary processor 1423 may be adapted to consume less power than the main processor 1421, or to be specific to a specified function. The auxiliary processor 1423 may be implemented as separate from, or as part of the main processor 1421. Thus, the processor 1420 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /disclosed functions, e.g., in a distributed manner. At least one processor may execute program instructions to achieve or perform various functions.

The auxiliary processor 1423 may control at least some of functions or states related to at least one component (e.g., the display module 1460, the sensor module 1476, or the communication module 1490) among the components of the electronic device 1401, instead of the main processor 1421 while the main processor 1421 is in an inactive (e.g., sleep) state, or together with the main processor 1421 while the main processor 1421 is in an active state (e.g., executing an application). According to an embodiment, the auxiliary processor 1423 (e.g., an image signal processor or a communication processor) may be implemented as part of another component (e.g., the camera module 1480 or the communication module 1490) functionally related to the auxiliary processor 1423. According to an embodiment, the auxiliary processor 1423 (e.g., the neural processing unit) may include a hardware structure specified for artificial intelligence model processing. An artificial intelligence model may be generated by machine learning. Such learning may be performed, e.g., by the electronic device 1401 where the artificial intelligence is performed or via a separate server (e.g., the server 1408). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1430 may store various data used by at least one component (e.g., the processor 1420 or the sensor module 1476) of the electronic device 1401. The various data may include, for example, software (e.g., the program 1440) and input data or output data for a command related thereto. The memory 1430 may include the volatile memory 1432 or the non-volatile memory 1434.

The program 1440 may be stored in the memory 1430 as software, and may include, for example, an operating system (OS) 1442, middleware 1444, or an application 1446.

The input module 1450 may receive a command or data to be used by another component (e.g., the processor 1420) of the electronic device 1401, from the outside (e.g., a user) of the electronic device 1401. The input module 1450 may include, for example, a microphone, a mouse, a keyboard, a key (e.g., a button), or a digital pen (e.g., a stylus pen).

The sound output module 1455 may output sound signals to the outside of the electronic device 1401. The sound output module 1455 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1460 may visually provide information to the outside (e.g., a user) of the electronic device 1401. The display module 1460 may include, for example, a display, a hologram device, or a projector and control circuitry to control a corresponding one of the display, hologram device, and projector. According to an embodiment, the display module 1460 may include a touch sensor adapted to detect a touch, or a pressure sensor adapted to measure the intensity of force incurred by the touch.

The audio module 1470 may convert a sound into an electrical signal and vice versa. According to an embodiment, the audio module 1470 may obtain the sound via the input module 1450, or output the sound via the sound output module 1455 or a headphone of an external electronic device (e.g., an electronic device 1402) directly (e.g., wiredly) or wirelessly coupled with the electronic device 1401.

The sensor module 1476 may detect an operational state (e.g., power or temperature) of the electronic device 1401 or an environmental state (e.g., a state of a user) external to the electronic device 1401, and then generate an electrical signal or data value corresponding to the detected state. According to an embodiment, the sensor module 1476 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1477 may support one or more specified protocols to be used for the electronic device 1401 to be coupled with the external electronic device (e.g., the electronic device 1402) directly (e.g., wiredly) or wirelessly. According to an embodiment, the interface 1477 may include, for example, a high definition multimedia interface (HDMI), a universal serial bus (USB) interface, a secure digital (SD) card interface, or an audio interface.

A connecting terminal 1478 may include a connector via which the electronic device 1401 may be physically connected with the external electronic device (e.g., the electronic device 1402). According to an embodiment, the connecting terminal 1478 may include, for example, an HDMI connector, a USB connector, an SD card connector, or an audio connector (e.g., a headphone connector).

The haptic module 1479 may convert an electrical signal into a mechanical stimulus (e.g., a vibration or a movement) or electrical stimulus which may be recognized by a user via his tactile sensation or kinesthetic sensation. According to an embodiment, the haptic module 1479 may include, for example, a motor, a piezoelectric element, or an electric stimulator.

The camera module 1480 may capture a still image or moving images. According to an embodiment, the camera module 1480 may include one or more lenses, image sensors, image signal processors, or flashes.

The power management module 1488 may manage power supplied to the electronic device 1401. According to an embodiment, the power management module 1488 may be implemented as at least part of, for example, a power management integrated circuit (PMIC).

The battery 1489 may supply power to at least one component of the electronic device 1401. According to an embodiment, the battery 1489 may include, for example, a primary cell which is not rechargeable, a secondary cell which is rechargeable, or a fuel cell.

The communication module 1490 may support establishing a direct (e.g., wired) communication channel or a wireless communication channel between the electronic device 1401 and the external electronic device (e.g., the electronic device 1402, the electronic device 1404, or the server 1408) and performing communication via the established communication channel. The communication module 1490 may include one or more communication processors that are operable independently from the processor 1420 (e.g., the application processor (AP)) and supports a direct (e.g., wired) communication or a wireless communication. According to an embodiment, the communication module 1490 may include a wireless communication module 1492 (e.g., a cellular communication module, a short-range wireless communication module, or a global navigation satellite system (GNSS) communication module) or a wired communication module 1494 (e.g., a local area network (LAN) communication module or a power line communication (PLC) module). A corresponding one of these communication modules may communicate with the external electronic device via the first network 1498 (e.g., a short-range communication network, such as Bluetooth™, wireless-fidelity (Wi-Fi) direct, or infrared data association (IrDA)) or the second network 1499 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1492 may identify and authenticate the electronic device 1401 in a communication network, such as the first network 1498 or the second network 1499, using subscriber information (e.g., international mobile subscriber identity (IMSI)) stored in the subscriber identification module 1496.

The wireless communication module 1492 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1492 may support a high-frequency band (e.g., the mmWave band) to achieve, e.g., a high data transmission rate. The wireless communication module 1492 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1492 may support various requirements specified in the electronic device 1401, an external electronic device (e.g., the electronic device 1404), or a network system (e.g., the second network 1499). According to an embodiment, the wireless communication module 1492 may support a peak data rate (e.g., 20Gbps or more) for implementing eMBB, loss coverage (e.g., 1464dB or less) for implementing mMTC, or U-plane latency (e.g., 0.5ms or less for each of downlink (DL) and uplink (UL), or a round trip of 14ms or less) for implementing URLLC.

The antenna module 1497 may transmit or receive a signal or power to or from the outside (e.g., the external electronic device) of the electronic device 1401. According to an embodiment, the antenna module 1497 may include an antenna including a radiating element including a conductive material or a conductive pattern formed in or on a substrate (e.g., a printed circuit board (PCB)). According to an embodiment, the antenna module 1497 may include a plurality of antennas (e.g., array antennas). In such a case, at least one antenna appropriate for a communication scheme used in the communication network, such as the first network 1498 or the second network 1499, may be selected, for example, by the communication module 1490 (e.g., the wireless communication module 1492) from the plurality of antennas. The signal or the power may then be transmitted or received between the communication module 1490 and the external electronic device via the selected at least one antenna. According to an embodiment, another component (e.g., a radio frequency integrated circuit (RFIC)) other than the radiating element may be additionally formed as part of the antenna module 1497.

According to various embodiments, the antenna module 1497 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1401 and the external electronic device 1404 via the server 1408 coupled with the second network 1499. Each of the electronic devices 1402 or 1404 may be a device of a same type as, or a different type, from the electronic device 1401. According to an embodiment, all or some of operations to be executed at the electronic device 1401 may be executed at one or more of the external electronic devices 1402, 1404, or 1408. For example, if the electronic device 1401 should perform a function or a service automatically, or in response to a request from a user or another device, the electronic device 1401, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1401. The electronic device 1401 may provide the outcome, with or without further processing of the outcome, as at least part of a reply to the request. To that end, a cloud computing, distributed computing, mobile edge computing (MEC), or client-server computing technology may be used, for example. The electronic device 1401 may provide ultra low-latency services using, e.g., distributed computing or mobile edge computing. In an embodiment, the external electronic device 1404 may include an internet-of-things (IoT) device. The server 1408 may be an intelligent server using machine learning and/or a neural network. According to an embodiment, the external electronic device 1404 or the server 1408 may be included in the second network 1499. The electronic device 1401 may be applied to intelligent services (e.g., smart home, smart city, smart car, or healthcare) based on 5G communication technology or IoT-related technology.

FIG. 15 is a block diagram 1500 illustrating an example configuration of a display module 1460 according to various embodiments.

Referring to FIG. 15, the display module 1460 may include a display 1510 and a display driver integrated circuit (DDI) (e.g., including circuitry) 1530 to control the display 1510. The DDI 1530 may include an interface module (e.g., including circuitry) 1531, memory 1533 (e.g., buffer memory), an image processing module (e.g., including various circuitry and/or executable program instructions) 1535, and/or a mapping module (e.g., including various circuitry and/or executable program instructions) 1537. The DDI 1530 may include various circuitry and receive image information that contains image data or an image control signal corresponding to a command to control the image data from another component of the electronic device 1401 via the interface module 1531. For example, according to an embodiment, the image information may be received from the processor 1420 (e.g., the main processor 1421 (e.g., an application processor)) or the auxiliary processor 1423 (e.g., a graphics processing unit) operated independently from the function of the main processor 1421. The DDI 1530 may communicate, for example, with touch circuitry 1550 or the sensor module 1476 via the interface module 1531. The DDI 1530 may also store at least part of the received image information in the memory 1533, for example, on a frame by frame basis. The image processing module 1535 may perform pre-processing or post-processing (e.g., adjustment of resolution, brightness, or size) with respect to at least part of the image data. According to an embodiment, the pre-processing or post-processing may be performed, for example, based at least in part on one or more characteristics of the image data or one or more characteristics of the display 1510. The mapping module 1537 may generate a voltage value or a current value corresponding to the image data pre-processed or post-processed by the image processing module 1535. According to an embodiment, the generating of the voltage value or current value may be performed, for example, based at least in part on one or more attributes of the pixels (e.g., an array, such as an RGB stripe or a pentile structure, of the pixels, or the size of each subpixel). At least some pixels of the display 1510 may be driven, for example, based at least in part on the voltage value or the current value such that visual information (e.g., a text, an image, or an icon) corresponding to the image data may be displayed via the display 1510.

According to an embodiment, the display module 1460 may further include the touch circuitry 1550. The touch circuitry 1550 may include a touch sensor 1551 and a touch sensor IC 1553 to control the touch sensor 1551. The touch sensor IC 1553 may control the touch sensor 1551 to sense a touch input or a hovering input with respect to a certain position on the display 1510. To achieve this, for example, the touch sensor 1551 may detect (e.g., measure) a change in a signal (e.g., a voltage, a quantity of light, a resistance, or a quantity of one or more electric charges) corresponding to the certain position on the display 1510. The touch circuitry 1550 may provide input information (e.g., a position, an area, a pressure, or a time) indicative of the touch input or the hovering input detected via the touch sensor 1551 to the processor 1420. According to an embodiment, at least part (e.g., the touch sensor IC 1553) of the touch circuitry 1550 may be formed as part of the display 1510 or the DDI 1530, or as part of another component (e.g., the auxiliary processor 1423) disposed outside the display module 1460.

According to an embodiment, the display module 1460 may further include at least one sensor (e.g., a fingerprint sensor, an iris sensor, a pressure sensor, or an illuminance sensor) of the sensor module 1476 or a control circuit for the at least one sensor. In such a case, the at least one sensor or the control circuit for the at least one sensor may be embedded in one portion of a component (e.g., the display 1510, the DDI 1530, or the touch circuitry 1550)) of the display module 1460. For example, when the sensor module 1476 embedded in the display module 1460 includes a biometric sensor (e.g., a fingerprint sensor), the biometric sensor may obtain biometric information (e.g., a fingerprint image) corresponding to a touch input received via a portion of the display 1510. As another example, when the sensor module 1476 embedded in the display module 1460 includes a pressure sensor, the pressure sensor may obtain pressure information corresponding to a touch input received via a partial or whole area of the display 1510. According to an embodiment, the touch sensor 1551 or the sensor module 1476 may be disposed between pixels in a pixel layer of the display 1510, or over or under the pixel layer.

The technical problems addressed in this disclosure are not limited to those described above, and other technical problems not mentioned herein will be clearly understood by those having ordinary knowledge in the art to which the present disclosure belongs.

As described above, according to an example embodiment. an electronic device 101 may comprise at least one processor 210 including processing circuitry. The electronic device 101 may comprise a display 220 including display driver circuitry 221, and a display panel 160 configured to provide a normal display mode displaying an image having a first viewing angle and a privacy display mode displaying an image having a second viewing angle narrower than the first viewing angle. The display panel 160 may include a circuit layer, a light emission layer disposed on the circuit layer, and a light-blocking layer, disposed above the light emission layer such that the normal display mode and the privacy display mode are provided, including light transmittance portions and a light-blocking portion surrounding the light transmittance portions. The display panel 160 may comprises sub-pixels defined by the circuit layer, the light emission layer, and the light-blocking layer. The sub-pixels may include a first sub-pixel 321-1 used for the normal display mode, and a second sub-pixel 322-1 used for both the normal display mode and the privacy display mode. The display driver circuitry 221 may be configured to display an image from the at least one processor 210 using both the first sub-pixel 321-1 and the second sub-pixel 322-1 in accordance with the normal display mode. The display driver circuitry 221 may be configured to, before a display mode provided by the display panel is switched from the normal display mode to the privacy display mode in accordance with a defined event, gradually reduce a brightness level provided via the first sub-pixel 321-1 to a defined brightness level. The display driver circuitry 221 may be configured to, based on the brightness level reduced to the defined brightness level, display an image from the at least one processor 210 using the second sub-pixel 322-1 from among the first sub-pixel 321-1 and the second sub-pixel 322-1 in accordance with the privacy display mode.

According to an example embodiment, the display driver circuitry 221 may be configured to, before a display mode provided by the display panel is switched from the normal display mode to the privacy display mode in accordance with the defined event, gradually increase a brightness level provided via the second sub-pixel 322-1 to defined another brightness level. The display driver circuitry 221 may be configured to, based on the brightness level, reduced to the defined brightness level, provided via the first sub-pixel 321-1 and the brightness level, increased to the defined other brightness level, provided via the second sub-pixel 322-1, display the image from the at least one processor 210 using the second sub-pixel 322-1 from among the first sub-pixel 321-1 and the second sub-pixel 322-1 in accordance with the privacy display mode.

According to an example embodiment, the display driver circuitry 221 may be configured to refrain from emitting using the first sub-pixel 321-1 in accordance with the privacy display mode.

According to an example embodiment, the display driver circuitry 221 may be configured to, for gradually reducing the brightness level provided via the first sub-pixel 321-1 to the defined brightness level before a display mode provided by the display panel is switched from the normal display mode to the privacy display mode in accordance with a defined event, identify a first grayscale level of a portion corresponding to the first sub-pixel 321-1 of an image from the at least one processor 210. The display driver circuitry 221 may be configured to, for gradually reducing the brightness level provided via the first sub-pixel 321-1 to the defined brightness level before a display mode provided by the display panel is switched from the normal display mode to the privacy display mode in accordance with a defined event, gradually reduce the first grayscale level to a second grayscale level representing a black color. The display driver circuitry 221 may be configured to, for gradually reducing the brightness level provided via the first sub-pixel 321-1 to the defined brightness level before a display mode provided by the display panel is switched from the normal display mode to the privacy display mode in accordance with a defined event, gradually reduce a data voltage applied to the first sub-pixel 321-1 from a first data voltage corresponding to the first grayscale level to a second data voltage corresponding to the second grayscale level, in accordance with gradually reducing from the first grayscale level to the second grayscale level. The brightness level, provided via the first sub-pixel 321-1 while an image from the at least one processor 210 using both the first sub-pixel 321-1 and the second sub-pixel 322-1 is displayed before a display mode provided by the display panel is switched from the normal display mode to the privacy display mode in accordance with the defined event, may be gradually reduced from a first brightness level according to the first data voltage to a second brightness level being the defined brightness level according to the second data voltage.

According to an example embodiment, the display driver circuitry 221 may be configured to, for gradually increasing the brightness level provided via the second sub-pixel 322-1 to the defined other brightness level before a display mode provided by the display panel is switched from the normal display mode to the privacy display mode in accordance with a defined event, identify a first luminance value set with respect to a portion corresponding to the second sub-pixel 322-1 of an image from the at least one processor 210. The display driver circuitry 221 may be configured to, for gradually increasing the brightness level provided via the second sub-pixel 322-1 to the defined other brightness level before a display mode provided by the display panel is switched from the normal display mode to the privacy display mode in accordance with a defined event, gradually increase the first luminance value to a second luminance value. The display driver circuitry 221 may be configured to, for gradually increasing the brightness level provided via the second sub-pixel 322-1 to the defined other brightness level before a display mode provided by the display panel is switched from the normal display mode to the privacy display mode in accordance with a defined event, gradually increase a data voltage applied to the second sub-pixel 322-1 from a third data voltage corresponding to the first luminance value to a fourth data voltage corresponding to the second luminance, in accordance with gradually increasing from the first luminance value to the second luminance value. The brightness level, provided via the second sub-pixel 322-1 while an image from the at least one processor 210 using both the first sub-pixel 321-1 and the second sub-pixel 322-1 is displayed before a display mode provided by the display panel is switched from the normal display mode to the privacy display mode in accordance with a defined event, may be gradually increased from a third brightness level according to the third data voltage to a fourth brightness level being the defined other brightness level according to the fourth data voltage.

According to an example embodiment, a brightness level of the image displayed using both the first sub-pixel 321-1 and the second sub-pixel 322-1 while the normal display mode is provided may be a fifth brightness level. A brightness level of the image displayed using the second sub-pixel 322-1 from among the first sub-pixel 321-1 and the second sub-pixel 322-1 while the privacy display mode is provided may be a sixth brightness level lower than the fifth brightness level. A brightness level of the image displayed using both the first sub-pixel 321-1 and the second sub-pixel 322-1 before a display mode provided by the display panel is switched from the normal display mode to the privacy display mode in accordance with a defined event, may be gradually reduced from the fifth brightness level to the sixth brightness level in accordance with gradually reducing the brightness level provided via the first sub-pixel 321-1 from the first brightness level to the second brightness level and gradually increasing the brightness level provided via the second sub-pixel 322-1 from the third brightness level to the fourth brightness level.

According to an example embodiment, a brightness level of an image displayed via the display panel 160 while the display mode of the display 220 is switched from the normal display mode to the privacy display mode may be substantially maintained as a brightness level of an image displayed via the display panel 160 while the normal display mode is provided.

According to an example embodiment, the display driver circuitry 221 may be configured to gradually reduce the brightness level provided via the first sub-pixel 321-1 to the defined brightness level during a time interval a first timing when the defined event is identified to a second timing when the privacy display mode is provided.

According to an example embodiment, a length of the time interval may be defined by a number of frames. The length of the time interval may be determined according to an illuminance value outside of the electronic device 101.

According to an example embodiment, the gradually reducing of the brightness level provided via the first sub-pixel 321-1 may be uniformly reduced in the time interval.

According to an example embodiment, the brightness level provided via the first sub-pixel 321-1 may be reduced by a first value in a first partial time including the first timing of the time interval. The brightness level provided via the first sub-pixel 321-1 may be reduced by the first value in a second partial time, including the second timing of the time interval, having a length corresponding to a length of the first partial time. The brightness level provided via the first sub-pixel 321-1 may be reduced by a second value greater than the first value in a third partial time between the first partial time and the second partial time.

According to an example embodiment, the electronic device 101 may comprise memory including one or more storage media storing instructions. The instructions, when executed by the at least one processor 210 individually or collectively, may cause the electronic device 101 to identify the defined event for switching the display mode of the display 220 from the normal display mode to the privacy display mode at a first timing. The instructions, when executed by the at least one processor 210 individually or collectively, may cause the electronic device 101 to transmit, to the display driver circuitry 221, commands indicating gradually reducing of the brightness level provided via the first sub-pixel 321-1 during a time interval between the first timing to a second timing when the privacy display mode is to be displayed. The display driver circuitry 221 may be configured to gradually reduce the brightness level provided via the first sub-pixel 321-1 to the defined brightness level in response to the received commands.

According to an example embodiment, a period in which the commands are transmitted may be determined according to an illuminance value outside of the electronic device 101.

According to an example embodiment, the sub-pixels may include a third sub-pixel used for the normal display mode and a fourth sub-pixel used for both the normal display mode and the privacy display mode. The first sub-pixel 321-1 and the second sub-pixel 322-1 may be arranged in a portion of a display area of the display panel 160. The third sub-pixel and the fourth sub-pixel may be arranged in another portion distinguished from the portion of the display area of the display panel 160. The display driver circuitry 221 may be configured to display, in the other portion of the display area, the image using the second sub-pixel 322-1 among the first sub-pixel 321-1 and the second sub-pixel 322-1 according to the privacy display mode, while displaying, in the portion of the display area, an image from the at least one processor 210 using both the third sub-pixel and the fourth sub-pixel according to the normal display mode.

According to an example embodiment, the privacy display mode may be a first privacy display mode. The display driver circuitry may be configured to, in accordance with a second privacy display mode displaying an image having a third viewing angle narrower than the first viewing angle and wider than the second viewing angle, display an image from the at least one processor using both the first sub-pixel and the second sub-pixel.

As described above, according to an example embodiment, an electronic device 101 may comprise at least one processor 210 including processing circuitry. The electronic device 101 may comprise a display 220 including display driver circuitry 221, and a display panel 160 configured to provide a normal display mode displaying an image having a first viewing angle and a privacy display mode displaying an image having a second viewing angle narrower than the first viewing angle. The display panel 160 may include a circuit layer, a light emission layer disposed on the circuit layer, and a light-blocking layer, disposed above the light emission layer such that the normal display mode and the privacy display mode are provided, including light transmittance portions and a light-blocking portion surrounding the light transmittance portions. The display panel 160 may comprise sub-pixels defined by the circuit layer, the light emission layer, and the light-blocking layer. The sub-pixels may include a first sub-pixel 321-1 used for the normal display mode, and a second sub-pixel 322-1 used for both the normal display mode and the privacy display mode. The display driver circuitry 221 may be configured to display an image from the at least one processor 210 using the second sub-pixel 322-1 from among the first sub-pixel 321-1 and the second sub-pixel 322-1 in accordance with the privacy display mode. The display driver circuitry 221 may be configured to, before a display mode provided by the display panel is switched from the privacy display mode to the normal display mode in accordance with a defined event, gradually increase a brightness level provided via the first sub-pixel 321-1 to a defined brightness level. The display driver circuitry 221 may be configured to, based on the brightness level increased to the defined brightness level, display an image from the at least one processor 210 using both the first sub-pixel 321-1 and the second sub-pixel 322-1 in accordance with the normal display mode.

According to an example embodiment, the display driver circuitry 221 may be configured to, before a display mode provided by the display panel is switched from the privacy display mode to the normal display mode in accordance with the defined event, gradually reduce a brightness level provided via the second sub-pixel 322-1 to defined another brightness level. The display driver circuitry 221 may be configured to, based on the brightness level, increased to the defined brightness level, provided via the first sub-pixel 321-1 and the brightness level, reduced to the defined other brightness level, provided via the second sub-pixel 322-1, display the image from the at least one processor 210 using both the first sub-pixel 321-1 and the second sub-pixel 322-1 in accordance with the normal display mode.

According to an example embodiment, the display driver circuitry 221 may be configured to refrain from emitting using the first sub-pixel 321-1 in accordance with the privacy display mode.

According to an example embodiment, the display driver circuitry 221 may be configured to, for gradually increasing the brightness level provided via the first sub-pixel 321-1 to the defined brightness level before a display mode provided by the display panel is switched from the privacy display mode to the normal display mode in accordance with the defined event, identify a first grayscale level of a portion corresponding to the first sub-pixel 321-1 of an image from the at least one processor 210. The display driver circuitry 221 may be configured to, for gradually increasing the brightness level provided via the first sub-pixel 321-1 to the defined brightness level before a display mode provided by the display panel is switched from the privacy display mode to the normal display mode in accordance with the defined event, gradually increase a second grayscale level representing a black color to the first grayscale level. The display driver circuitry 221 may be configured to, for gradually increasing the brightness level provided via the first sub-pixel 321-1 to the defined brightness level before a display mode provided by the display panel is switched from the privacy display mode to the normal display mode in accordance with the defined event, gradually increase a data voltage applied to the first sub-pixel 321-1 from a second data voltage corresponding to the second grayscale level to a first data voltage corresponding to the first grayscale level, in accordance with gradually increasing from the second grayscale level to the first grayscale level. The brightness level, provided via the first sub-pixel 321-1 while an image from the at least one processor 210 using both the first sub-pixel 321-1 and the second sub-pixel 322-1 is displayed before a display mode provided by the display panel is switched from the privacy display mode to the normal display mode in accordance with the defined event, may be gradually increased from a second brightness level according to the second data voltage to a first brightness level being the defined brightness level according to the first data voltage.

According to an example embodiment, the display driver circuitry 221 may be configured to, for gradually reducing the brightness level provided via the second sub-pixel 322-1 to the defined other brightness level before a display mode provided by the display panel is switched from the privacy display mode to the normal display mode in accordance with the defined event, identify a second luminance value set with respect to a portion corresponding to the second sub-pixel 322-1 of an image from the at least one processor 210. The display driver circuitry 221 may be configured to, for gradually reducing the brightness level provided via the second sub-pixel 322-1 to the defined other brightness level before a display mode provided by the display panel is switched from the privacy display mode to the normal display mode in accordance with the defined event, gradually reduce the second luminance value to a first luminance value. The display driver circuitry 221 may be configured to, for gradually reducing the brightness level provided via the second sub-pixel 322-1 to the defined other brightness level before a display mode provided by the display panel is switched from the privacy display mode to the normal display mode in accordance with the defined event, gradually reduce a data voltage applied to the second sub-pixel 322-1 from a fourth data voltage corresponding to the second luminance to a third data voltage corresponding to the first luminance value, in accordance with gradually reducing from the second luminance value to the first luminance value. The brightness level, provided via the second sub-pixel 322-1 while an image from the at least one processor 210 using both the first sub-pixel 321-1 and the second sub-pixel 322-1 is displayed before a display mode provided by the display panel is switched from the privacy display mode to the normal display mode in accordance with the defined event, is gradually reduced from a fourth brightness level according to the fourth data voltage to a third brightness level being the defined other brightness level according to the third data voltage.

According to an example embodiment, a brightness level of the image displayed using the second sub-pixel 322-1 from among the first sub-pixel 321-1 and the second sub-pixel 322-1 while the privacy display mode is provided may be a sixth brightness level. A brightness level of the image displayed using both the first sub-pixel 321-1 and the second sub-pixel 322-1 while the normal display mode is provided may be a fifth brightness level higher than the sixth brightness level. A brightness level of the image displayed using both the first sub-pixel 321-1 and the second sub-pixel 322-1 before a display mode provided by the display panel is switched from the privacy display mode to the normal display mode in accordance with a defined event, may be gradually increased from the sixth brightness level to the fifth brightness level in accordance with gradually increasing the brightness level provided via the first sub-pixel 321-1 from the second brightness level to the first brightness level and gradually reducing the brightness level provided via the second sub-pixel 322-1 from the fourth brightness level to the third brightness level.

According to an example embodiment, the privacy display mode may be a first privacy display mode. The display driver circuitry may be configured to display an image from the at least one processor using the first sub-pixel and the second sub-pixel, according to a second privacy display mode for displaying an image having a third viewing angle narrower than the first viewing angle and wider than the second viewing angle.

As described above, according to an example embodiment, an electronic device 101 may comprise a processor 210. The electronic device 101 may comprise memory storing instructions. The electronic device 101 may comprise a display set to provide a first display mode observable at a first viewing angle and a second display mode observable at a second viewing angle narrower than the first viewing angle. The display 160 may include a pixel layer including a first pixel group 321 and a second pixel group 322. The display 160 may include a light-blocking layer forming a first light transmittance portion, disposed above the first pixel group 321, having a first width corresponding to the first viewing angle, and a second light transmittance portion, disposed above the second pixel group 322, having a second width smaller than the first width corresponding to the second viewing angle. The instructions, when executed by the processor 210 individually or collectively, may cause the electronic device to display, at the first display mode, via the first pixel group 321 and the second pixel group 322, a first screen corresponding to the first display mode. The instructions, when executed by the processor 210 individually or collectively, may cause the electronic device to display, at the second display mode, via the second pixel group 322, a second screen corresponding to the second display mode. The first pixel group 321 may be turned off or turned on to have a limited grayscale. The instructions, when executed by the processor 210 individually or collectively, may cause the electronic device to, when switching from the first display mode to the second display mode or from the second display mode to the first display mode, display, via at least a portion of at least one of the first pixel group 321 or the second pixel group 322, a plurality of transition frames between the first screen and the second screen.

According to an example embodiment, the instructions, when executed by the processor 210 individually or collectively, may cause the electronic device to display the plurality of transition frames such that at least one pixel included in the first pixel group 321 has a third grayscale between a first grayscale in the first screen and a second grayscale in the second screen in at least one frame among the plurality of transition frames.

According to an example embodiment, the instructions, when executed by the processor 210 individually or collectively, may cause the electronic device to, when switching from the first display mode to the second display mode, display the plurality of transition frames such that at least one pixel included in the first pixel group 321 has a third grayscale between the first grayscale and the second grayscale in a first transition frame, and a fourth grayscale between the second grayscale and the third grayscale in a second transition frame next to the first transition frame.

According to an example embodiment, the instructions, when executed by the processor 210 individually or collectively, may cause the electronic device to, when switching from the second display mode to the first display mode, display the plurality of transition frames such that at least one pixel included in the first pixel group 321 has a third grayscale between the first grayscale and the second grayscale in a third transition frame, and a fifth grayscale between the first grayscale and the third grayscale in a fourth transition frame next to the third transition frame.

According to an example embodiment, the instructions, when executed by the processor 210 individually or collectively, may cause the electronic device to, based on a third brightness curve different from a first brightness curve used in the first display mode and a second brightness curve used in the second display mode, display the plurality of transition frames.

According to an example embodiment, the instructions, when executed by the processor 210 individually or collectively, may cause the electronic device to, when switching from the first display mode to the second display mode, display the plurality of transition frames based on the third brightness curve. The instructions, when executed by the processor 210 individually or collectively, may cause the electronic device to, when switching from the second display mode to the first display mode, display other plurality of transition frames based on a fourth brightness curve different from the first brightness curve, the second brightness curve, and the third brightness curve.

According to an example embodiment, the instructions, when executed by the processor 210 individually or collectively, may cause the electronic device to, when switching from the first display mode to the second display mode or from the second display mode to the first display mode, in a case that a designated condition is satisfied, display the plurality of transition frames based on a fifth brightness curve different from the first brightness curve, the second brightness curve, the third brightness curve, and the fourth brightness curve.

According to an example embodiment, the designated condition may include that a difference between a first luminance of the first screen and a second luminance of the second screen is within a designated range.

According to an example embodiment, at least one of the third brightness curve, the fourth brightness curve, or the fifth brightness curve may be determined based on at least one of the first brightness curve or the second brightness curve.

According to an example embodiment, at least one of the third brightness curve, the fourth brightness curve, or the fifth brightness curve may include at least one of a linear curve, a gamma curve, or a S curve.

According to an example embodiment, the instructions, when executed by the processor 210 individually or collectively, may cause the electronic device to, based on at least one of the first grayscale, the second grayscale, the third grayscale, the fourth grayscale, the fifth grayscale, the first brightness curve, the second brightness curve, the third brightness curve, the fourth brightness curve, or the fifth brightness curve, determine the number of the plurality of transition frames.

According to an example embodiment, the number of the plurality of transition frames may be one of 2 to 32.

According to an example embodiment, the electronic device may further comprise at least one sensor. The instructions, when executed by the processor 210 individually or collectively, may cause the electronic device to, using the at least one sensor, obtain at least one information associated with a peripheral environment of the electronic device. The instructions, when executed by the processor 210 individually or collectively, may cause the electronic device to, further based on the at least one information, determine the number of the plurality of transition frames.

According to an example embodiment, the instructions, when executed by the processor 210 individually or collectively, may cause the electronic device to, based on at least one of the first grayscale, the second grayscale, the third grayscale, the fourth grayscale, the fifth grayscale, the first brightness curve, the second brightness curve, the third brightness curve, the fourth brightness curve, or the fifth brightness curve, determine a driving frequency to display the plurality of transition frames.

According to an example embodiment, the electronic device may further comprise at least one sensor. The instructions, when executed by the processor 210 individually or collectively, may cause the electronic device to, using the at least one sensor, obtain at least one information associated with a peripheral environment of the electronic device. The instructions, when executed by the processor 210 individually or collectively, may cause the electronic device to, further based on the at least one information, determine the driving frequency to display the plurality of transition frames.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as "A or B," "at least one of A and B," "at least one of A or B," "A, B, or C," "at least one of A, B, and C," and "at least one of A, B, or C," may include any one of or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively", as "coupled with," or "connected with" another element (e.g., a second element), the element may be coupled with the other element directly (e.g., wiredly), wirelessly, or via a third element.

As used in connection with various embodiments of the disclosure, the term "module" may include a unit implemented in hardware, software, or firmware, or any combination thereof, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1440) including one or more instructions that are stored in a storage medium (e.g., internal memory 1436 or external memory 1438) that is readable by a machine (e.g., the electronic device 1401). For example, a processor (e.g., the processor 1420) of the machine (e.g., the electronic device 1401) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the "non-transitory" storage medium is a tangible device, and may not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
at least one processor comprising processing circuitry;
memory storing instructions; and
a display configured to provide a first display mode observable at a first viewing angle and a second display mode observable at a second viewing angle narrower than the first viewing angle,
wherein the display includes:
a pixel layer including a first pixel group and a second pixel group; and
a light-blocking layer forming a first light transmittance portion, disposed above the first pixel group, having a first width corresponding to the first viewing angle, and a second light transmittance portion, disposed above the second pixel group, having a second width smaller than the first width corresponding to the second viewing angle,
wherein the instructions, when executed by the at least one processor individually and/or collectively, cause the electronic device to:
display, in the first display mode, via the first pixel group and the second pixel group, a first screen corresponding to the first display mode; and
display, in the second display mode, via the second pixel group, a second screen corresponding to the second display mode, wherein the first pixel group is turned off or turned on to have a limited grayscale; and
based on switching from the first display mode to the second display mode or from the second display mode to the first display mode, display, via at least a portion of at least one of the first pixel group or the second pixel group, a plurality of transition frames between the first screen and the second screen.

2. The electronic device of claim 1, wherein the instructions, when executed by the at least one processor individually and/or collectively, cause the electronic device to:
display the plurality of transition frames such that at least one pixel included in the first pixel group has a third grayscale between a first grayscale in the first screen and a second grayscale in the second screen in at least one frame among the plurality of transition frames.

3. The electronic device of claim 2, wherein the instructions, when executed by the at least one processor individually and/or collectively, cause the electronic device to:
based on switching from the first display mode to the second display mode, display the plurality of transition frames such that at least one pixel included in the first pixel group has a third grayscale between the first grayscale and the second grayscale in a first transition frame, and a fourth grayscale between the second grayscale and the third grayscale in a second transition frame next to the first transition frame.

4. The electronic device of claim 2, wherein the instructions, when executed by the at least one processor individually and/or collectively, cause the electronic device to:
based on switching from the second display mode to the first display mode, display the plurality of transition frames such that at least one pixel included in the first pixel group has a third grayscale between the first grayscale and the second grayscale in a third transition frame, and a fifth grayscale between the first grayscale and the third grayscale in a fourth transition frame next to the third transition frame.

5. The electronic device of claim 1, wherein the instructions, when executed by the at least one processor individually and/or collectively, cause the electronic device to:
based on a third brightness curve different from a first brightness curve used in the first display mode and a second brightness curve used in the second display mode, display the plurality of transition frames.

6. The electronic device of claim 5, wherein the instructions, when executed by the at least one processor individually and/or collectively, cause the electronic device to:
based on switching from the first display mode to the second display mode, display the plurality of transition frames based on the third brightness curve, and
based on switching from the second display mode to the first display mode, display another plurality of transition frames based on a fourth brightness curve different from the first brightness curve, the second brightness curve, and the third brightness curve.

7. The electronic device of claim 6, wherein the instructions, when executed by the at least one processor individually and/or collectively, cause the electronic device to:
based on switching from the first display mode to the second display mode or from the second display mode to the first display mode, based on a designated condition being satisfied, display the plurality of transition frames based on a fifth brightness curve different from the first brightness curve, the second brightness curve, the third brightness curve, and the fourth brightness curve.

8. The electronic device of claim 7, wherein the designated condition includes a difference between a first luminance of the first screen and a second luminance of the second screen being within a designated range.

9. The electronic device of claim 8, wherein at least one of the third brightness curve, the fourth brightness curve, or the fifth brightness curve is determined based on at least one of the first brightness curve and/or the second brightness curve.

10. The electronic device of claim 9, wherein the instructions, when executed by the at least one processor individually and/or collectively, cause the electronic device to:
based on at least one of the first grayscale, the second grayscale, the third grayscale, the fourth grayscale, the fifth grayscale, the first brightness curve, the second brightness curve, the third brightness curve, the fourth brightness curve, and/or the fifth brightness curve, determine the number of the plurality of transition frames.

11. The electronic device of claim 10, wherein the electronic device further comprises at least one sensor,
wherein the instructions, when executed by the at least one processor individually and/or collectively, cause the electronic device to:
using the at least one sensor, obtain at least one information associated with a peripheral environment of the electronic device, and
based on the at least one information, determine the number of the plurality of transition frames.

12. The electronic device of claim 9, wherein the instructions, when executed by the at least one processor individually and/or collectively, cause the electronic device to:
based on at least one of the first grayscale, the second grayscale, the third grayscale, the fourth grayscale, the fifth grayscale, the first brightness curve, the second brightness curve, the third brightness curve, the fourth brightness curve, and/or the fifth brightness curve, determine a driving frequency to display the plurality of transition frames.

13. The electronic device of claim 12, wherein the electronic device further comprises at least one sensor,
wherein the instructions, when executed by the at least one processor individually and/or collectively, cause the electronic device to:
using the at least one sensor, obtain at least one information associated with a peripheral environment of the electronic device, and
based on the at least one information, determine the driving frequency to display the plurality of transition frames.

14. An electronic device comprising:
at least one processor comprising processing circuitry; and
a display including display driver circuitry, and a display panel configured to provide a normal display mode displaying an image having a first viewing angle and a privacy display mode displaying an image having a second viewing angle narrower than the first viewing angle,
wherein the display panel includes:
a circuit layer;
a light emission layer disposed on the circuit layer; and
a light-blocking layer, disposed above the light emission layer such that the normal display mode and the privacy display mode are provided, including light transmittance portions and a light-blocking portion surrounding the light transmittance portions,
wherein the display panel comprises sub-pixels defined by the circuit layer, the light emission layer, and the light-blocking layer,
wherein the sub-pixels include:
a first sub-pixel configured for the normal display mode, and
a second sub-pixel configured for both the normal display mode and the privacy display mode,
wherein the display driver circuitry is configured to:
display an image from the at least one processor using both the first sub-pixel and the second sub-pixel in accordance with the normal display mode;
before a display mode provided by the display panel is switched from the normal display mode to the privacy display mode in accordance with a defined event, gradually reduce a brightness level provided via the first sub-pixel to a defined brightness level; and
based on the brightness level reduced to the defined brightness level, display an image from the at least one processor using the second sub-pixel from among the first sub-pixel and the second sub-pixel in accordance with the privacy display mode.

15. The electronic device of claim 14,
wherein the display driver circuitry is configured to:
before a display mode provided by the display panel is switched from the normal display mode to the privacy display mode in accordance with the defined event, gradually increase a brightness level provided via the second sub-pixel to defined another brightness level; and
based on the brightness level, reduced to the defined brightness level, provided via the first sub-pixel and the brightness level, increased to the defined other brightness level, provided via the second sub-pixel, display the image from the at least one processor using the second sub-pixel from among the first sub-pixel and the second sub-pixel in accordance with the privacy display mode.

16. The electronic device of claim 15,
wherein the display driver circuitry is configured to:
refrain from emitting using the first sub-pixel in accordance with the privacy display mode.

17. The electronic device of claim 15,
wherein the display driver circuitry is configured to:
for gradually reducing the brightness level provided via the first sub-pixel to the defined brightness level before a display mode provided by the display panel is switched from the normal display mode to the privacy display mode in accordance with a defined event:
identify a first grayscale level of a portion corresponding to the first sub-pixel of an image from the at least one processor;
gradually reduce the first grayscale level to a second grayscale level representing a black color; and
gradually reduce a data voltage applied to the first sub-pixel from a first data voltage corresponding to the first grayscale level to a second data voltage corresponding to the second grayscale level, in accordance with gradually reducing from the first grayscale level to the second grayscale level,
wherein the brightness level, provided via the first sub-pixel while an image from the at least one processor using both the first sub-pixel and the second sub-pixel is displayed before a display mode provided by the display panel is switched from the normal display mode to the privacy display mode in accordance with the defined event, is gradually reduced from a first brightness level according to the first data voltage to a second brightness level being the defined brightness level according to the second data voltage.

18. The electronic device of claim 15,
wherein the display driver circuitry is configured to:
for gradually increasing the brightness level provided via the second sub-pixel to the defined other brightness level before a display mode provided by the display panel is switched from the normal display mode to the privacy display mode in accordance with a defined event:
identify a first luminance value set with respect to a portion corresponding to the second sub-pixel of an image from the at least one processor;
gradually increase the first luminance value to a second luminance value; and
gradually increase a data voltage applied to the second sub-pixel from a third data voltage corresponding to the first luminance value to a fourth data voltage corresponding to the second luminance, in accordance with gradually increasing from the first luminance value to the second luminance value,
wherein the brightness level, provided via the second sub-pixel while an image from the at least one processor using both the first sub-pixel and the second sub-pixel is displayed before a display mode provided by the display panel is switched from the normal display mode to the privacy display mode in accordance with a defined event, is gradually increased from a third brightness level according to the third data voltage to a fourth brightness level being the defined other brightness level according to the fourth data voltage.

19. The electronic device of claim 18,
wherein a brightness level of the image displayed using both the first sub-pixel and the second sub-pixel while the normal display mode is provided is a fifth brightness level,
wherein a brightness level of the image displayed using the second sub-pixel from among the first sub-pixel and the second sub-pixel while the privacy display mode is provided is a sixth brightness level lower than the fifth brightness level, and
wherein a brightness level of the image displayed using both the first sub-pixel and the second sub-pixel before a display mode provided by the display panel is switched from the normal display mode to the privacy display mode in accordance with a defined event, is gradually reduced from the fifth brightness level to the sixth brightness level in accordance with gradually reducing the brightness level provided via the first sub-pixel from the first brightness level to the second brightness level and gradually increasing the brightness level provided via the second sub-pixel from the third brightness level to the fourth brightness level.

20. An electronic device comprising:
at least one processor comprising processing circuitry; and
a display including display driver circuitry, and a display panel configured to provide a normal display mode displaying an image having a first viewing angle and a privacy display mode displaying an image having a second viewing angle narrower than the first viewing angle,
wherein the display panel includes:
a circuit layer;
a light emission layer disposed on the circuit layer; and
a light-blocking layer, disposed above the light emission layer and configured such that the normal display mode and the privacy display mode are provided, including light transmittance portions and a light-blocking portion surrounding the light transmittance portions,
wherein the display panel comprises sub-pixels defined by the circuit layer, the light emission layer, and the light-blocking layer, and
wherein the sub-pixels include:
a first sub-pixel configured to be used for the normal display mode, and
a second sub-pixel configured to be used for both the normal display mode and the privacy display mode,
wherein the display driver circuitry is configured to:
display an image from the at least one processor using the second sub-pixel from among the first sub-pixel and the second sub-pixel in accordance with the privacy display mode;
before a display mode provided by the display panel is switched from the privacy display mode to the normal display mode in accordance with a defined event, gradually increase a brightness level provided via the first sub-pixel to a defined brightness level; and
based on the brightness level increased to the defined brightness level, display an image from the at least one processor using both the first sub-pixel and the second sub-pixel in accordance with the normal display mode.
